(19) United States
(12) Patent Application Publication
(10) Pub. No.: US 2019/0052553 A1
(43) Pub. Date: Feb. 14, 2019

(54) ARCHITECTURES AND METHODS FOR DEEP PACKET INSPECTION USING ALPHABET AND BITMAP-BASED COMPRESSION

(71) Applicant: Intel Corporation, Santa Clara, CA (US)

(72) Inventors: Shiva Shankar Subramanian, Singapore (SG); Pinxing Lin, Singapore (SG)

(21) Appl. No.: 15/941,469

(22) Filed: Mar. 30, 2018

Related U.S. Application Data
(60) Provisional application No. 62/635,689, filed on Feb. 27, 2018.
(60) Provisional application No. 62/635,708, filed on Feb. 27, 2018.
(60) Provisional application No. 62/636,256, filed on Feb. 28, 2018.
(60) Provisional application No. 62/636,707, filed on Feb. 28, 2018.
(60) Provisional application No. 62/639,104, filed on Mar. 6, 2018.

(51) Int. Cl. H04L 12/26; H04L 12/811; H04L 29/06; G06F 9/448

(52) U.S. Cl. CPC H04L 43/028; H04L 43/026; H03M 7/3084; H04L 69/22; G06F 9/4498; H04L 47/38

(57) ABSTRACT

A signature matching hardware accelerator systems and methods for deep packet inspection (DPI) applies two different compression processes to a deterministic finite automaton (DFA) used for content awareness application processing of packet flows in a communication network. Signatures related to awareness content are represented through simple strings or regular expressions in a database and are converted into a automaton, which is a state machine using the characters and state transitions to match data in incoming packets. The two compression processes include applying an alphabet compression process to reduce redundant characters and related state transitions, and then applying a two dimensional bitmap-based compression process to further reduce redundant state transitions.

### CROSS-REFERENCE TO RELATED APPLICATIONS

This application claims benefit of priority under 35 U.S.C.119(e) to co-pending U.S. Application Ser. No. 62/635,689, filed Feb. 27, 2018 under the same title; U.S. Application Ser. No. 62/635,708, filed Feb. 27, 2018 titled CONTENT-BASED BYTE INTERLEAVING IN DEEP PACKET INSPECTION FOR LINE RATE SIGNATURE MATCHING; U.S. Application Ser. No. 62/636,256, filed Feb. 28, 2018 titled PACKED STORAGE ARCHITECTURE AND METHODS OF STORING BITMASKS IN DEEP PACKET INSPECTION SIGNATURE MATCHING; U.S. Application Ser. No. 62/636,707, filed Feb. 28, 2018, titled DETERMINISTIC FINITE AUTONOMA AND CONTROL DATA COMPRESSION IN DEEP PACKET INSPECTION SIGNATURE MATCHING; and U.S. Application Ser. No. 62/639,104, filed Mar. 6, 2018, titled COMPRESSION TECHNIQUE-INDEPENDENT HARDWARE ACCELERATOR SIGNATURE MATCHING ENGINE, all by the same inventors of the subject application and all fully incorporated herein by their reference.

### FIELD

The present disclosure relates to deep packet inspection (DPI) methodologies in distributed network systems and in particular, to architectures and methods to more efficiently perform DPI in network traffic streams.

### BACKGROUND

Modern communication networks are increasingly utilizing content aware technologies to improve efficiencies and streamline data delivery and security. Content-aware processing is often utilized at the front end of distributed network systems for application data identification in, for example, quality of service (QoS) applications, identification of various security threats in anti-virus or anti-malware applications or other purposes.

Deep packet inspection (DPI) is the process of inspecting a complete network packet including, optionally, its headers at various OSI layers and the packet payload. DPI is the technology that enables content aware networking by inspecting data payloads of network traffic and comparing with a database of patterns or indicators (referred to as “signatures”) to perform the function of a particular content-aware application. However, unlike header inspection, where the location of particular data in a packet header is known, the location of the signature(s) in data payloads is generally unknown. Consequently, all the bytes in the packet payloads of a data stream should be compared against a signature database, which makes DPI a time and processing intensive task.

The signatures used for DPI can be represented as simple strings or regular expressions and converted into a functionally equivalent data pattern and automated analysis process using states/state transitions based on the data pattern, referred to as finite automata or deterministic finite automata (DFA). DFA is used in processor-based systems for comparison of signatures to data in packets, referred to as “signature matching.” An automaton is a finite state machine with multiple nodes and directed edges between the nodes based on the converted data pattern of signatures. The nodes are the “states” and the directed edges represent the “state transitions.” An automaton has a single root state from which the state traversal starts. Each and every byte in the packet payload is passed to the automaton which provides the next state corresponding to the payload byte. If the computed next state corresponding to a sequence of payload bytes leads to an accepting state (subset of states among all states), a signature maybe considered to be matched, i.e., the inspected packet contains the content that is being searched.

The ever-increasing speed and bandwidth of data flows in network communications make signature matching increasingly challenging at high rates, e.g., on the order of 5-10 Gbps and higher. Therefore, continuous improvements to DPI signature matching processing and hardware efficiencies are similarly desired.

### BRIEF DESCRIPTION OF THE DRAWINGS

Certain examples of circuits, apparatuses and/or methods will be described in the following by way of example only in reference to the accompanying drawing figures where:

FIG. 1A depicts a typical architecture of a distributed network system that facilitates deep packet inspection (DPI) according to one embodiment of the disclosure;

FIG. 1B depicts a hardware accelerator configured to perform deep packet inspection in a network, according to one embodiment of the disclosure;

FIGS. 2(A)-(F) depict various stages of a technique for compressing a deterministic finite automaton (DFA) using bitmaps and bitmasks according to certain embodiments;

FIGS. 3(A)-(D) provide a general overview one example embodiment of what data is stored and how that data is stored in memory for transition decompression;

FIG. 4 shows a diagram of a process for DFA compression according to various embodiments;

FIGS. 5 (A) and (B) show the top level architecture and a description of a DFA decompression engine according to one embodiment;

FIG. 6 shows the internal block level architecture of the DFA decompression engine according to one embodiment;

FIGS. 7(A) and (B) illustrate an example of LTT Address Calculation Circuitry is shown according to various embodiments;

FIG. 8 illustrates address computation performed by an accumulative parallel counter (APC) circuit according to one embodiment of the disclosure;

FIGS. 9 (A) and (B) show an example embodiment for a parallel adder circuit for N set to 16 together with a 4 bit initial value;

FIG. 10 shows and example embodiment of MBT Address calculation circuitry to calculate the address location of a bitmask;

FIG. 11 illustrates an example embodiment for MTT address calculation circuitry similar to the LTT address calculation circuitry of FIG. 7;

FIGS. 12(A) and (B) respectively show circuitry for a next state assignment and circuitry for a current state assignment according to various embodiments;

FIGS. 13(A) and (B) respectively illustrate another example of a signature set to automata conversion for the specific set of signature's “abc” and “egh” according to various embodiments;

FIG. 14 illustrates an example of alphabet compression according to various embodiments of the inventions;

FIGS. 15 (A) and (B) illustrate a respective comparison of bitmap compressed automaton without and then with a process of alphabet compression according to various embodiments;

FIGS. 16 and 17 illustrate embodiments to implement alphabet compression a bitmap-based compression Hardware Decompression Engine;

FIG. 18 is a flow diagram illustrating a method 1800 for signature mating in deep packet inspection (DPI) using a combination of alphabet compression and bit-map based compression techniques of the inventive embodiments;

FIG. 19 illustrates one embodiment for signature matching in a hardware-based transition decompression function according to various embodiments;

FIG. 20 illustrates a timing diagram for interleaving bits based on contexts according to one embodiment;

FIG. 21 illustrates various embodiments for converting packet streams into contexts using a rules based decision engine according to certain embodiments;

FIG. 22 illustrates an example method for context-based streaming according to one or more embodiments;

FIGS. 23 and 24 illustrate examples of storage of DFA compression information in the memory circuit of a hardware accelerator according to a sequential storage method and its wasted memory usage respectively;

FIG. 25 illustrates one example embodiment for storing compressed deterministic finite automaton (DFA) information in a hardware acceleration circuit memory using a packed storage architecture (PSA) with physical memory partitioning to support bitmask accesses across multiple physical memory entries of one embodiment;

FIGS. 26A-26D illustrate various examples of fetching uncompressed bitmasks requiring retrieval in one clock cycle of the hardware accelerator according to certain aspects of inventive embodiments; The next step is to extract the necessary bitmask from the reconstructed data for further processing

FIG. 27 illustrates memory addressing for reconstructing compressed DFA information (e.g., bitmasks) according to one or more example embodiments;

FIG. 28 illustrates an example embodiment for a method to extract bitmasks from the reconstructed data of FIG. 27;

FIG. 29 illustrates example hardware logic for to fetch bitmask information from memory of the hardware accelerator in a single clock cycle, according to one example embodiment;

FIG. 30 illustrates a functional block diagram for a DPI hardware accelerator that performs DFA transition decompression according to certain example embodiments;

FIG. 31 is a basic flowchart illustrating methods for compressing and fetching phases using bitmap and bitmask based compression of DFA in a signature matching hardware accelerator system, according to example packed storage architecture embodiments of the disclosure;

FIG. 32 shows a process 8100 of transition compression performed on the specific combination of signatures ‘acd’, ‘bh’ and ‘gh’ according to various embodiments;

FIG. 33 shows a process for bitmask compression where FIG. 33(a) shows the reorganized member states and FIG. 33(b) shows the bitmask compression performed in the example embodiment;

FIG. 34 shows the pseudocode process for the state reorganization algorithm used for bitmask compression according to various embodiments;

FIG. 35 is a block diagram illustrating compressing an automaton or a DFA through multiple levels to its most efficient compressed form according to certain embodiments;

FIG. 36 shows an overview of processing 8500 that may be performed as part of the transition decompression when the DFA is compressed;

FIG. 37 describes an embodiment of “Deep Packet Inspection Accelerator” (DPIA) 9300 system architecture which may perform signature matching at line rates;

FIG. 38 details a functional block level architecture of a DPIA circuitry 9300, according to one embodiment;

FIG. 39 shows one example embodiment for a scalable DPIA 9400 architecture with N instances of SMEs 9410 demonstrating the scalability of the DPIA architecture of various embodiments;

FIG. 40 shows one example functional block architecture of an SME 9300 of various embodiments;

FIG. 41 illustrates post-processing actions are stored in memory (not on-chip SRAM memories) corresponding to the signature matches; and

FIG. 42 illustrates a flowchart 9700 of events occurring as part of the hardware software co-architecture in DPIA.

### DETAILED DESCRIPTION

As indicated previously, DPI methodologies may inspect the packets of an incoming data stream to perform signature matching. DPI signature matching generally inspects both the header and data portions of the data packet or headers and protocol data units (PDUs) at various layers of the open systems interconnection (OSI) model. This “deep” inspection makes signature matching a very computationally challenging task, as each byte of the data stream has to be compared with a database of signatures, and is often a bottleneck/limitation in the rate of communications achievable in a network. For example, in distributed DPI enabled networks, DPI is often performed at relatively small end-user devices having network interface circuit or card (NIC) such as modems, routers, access points, personal and handheld computing devices, on real-time data flows at wire-speed, or “line rate.” Accordingly, such devices must be able to rapidly and efficiently perform DPI on incoming data streams in order to avoid potential packet loss and/or overloading device memory buffers.

With the increasing bandwidth and low-latency requirements for DPI, accelerating signature matching becomes crucial in content aware network devices. Deterministic finite automata (DFA)-based solutions have become the industry standard for accelerated signature matching in DPI because of the ability to compress/simplify the amount of data required to be analyzed.

As mentioned previously, the DFA comprises a state table representing the database of digital signatures as defined by a plurality of states and state transitions relating to character expressions of the digital signatures. DFA may require a large memory to store all possible combinations of next state transitions. However, since a deterministic finite automaton generally has many redundant state transitions, it contains a huge amount of redundant data which may generally be simplified using transition compression algorithms such a bitmap based compression.

Embodiments of the present invention relate to using two different compression processes to compress an automaton used in DPI signature matching including: (1) applying a first compression technique using alphabet compression to reduce a number of indistinguishable characters and corresponding state transitions of the automaton; and (2) applying a second compression technique using bitmap-based compression applied to said automaton using the reduced results of the first compression technique.

The combination of alphabet compression and bitmap based compression techniques results in additional transitions able to be compressed, of the order of 5-10% across various signature sets. In bitmap compression automaton/signature sets are compressed by simplifying the redundant state transitions using bitmaps and bitmasks. However, certain characters in the state table are indistinguishable due to the characteristics of the signature sets. The state transitions belonging to these characters cannot be compressed by bitmap-based compression techniques. However, Alphabet compression can be used to efficiently compress these redundant state transitions. Example embodiments of both compression techniques, their combination, and architecture implementations are described below.

A general DPI-capable network system will be described first, followed secondly by a description of example embodiments of a bitmap-based compression process and related compressed storage and high throughput architectures; and lastly followed by alphabet compression technique and modification of bitmap processing and architecture in further inventive embodiments.

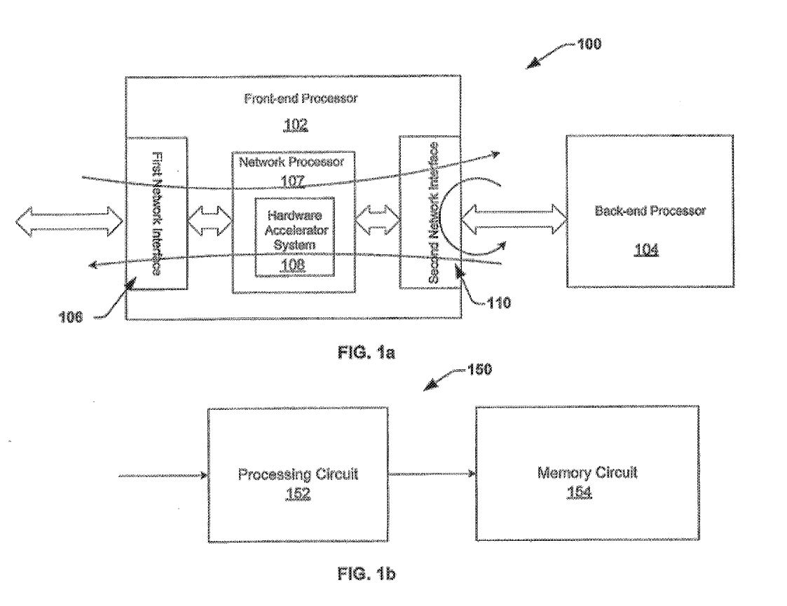

FIG. 1a depicts a typical architecture of a distributed network system 100 that facilitates deep packet inspection (DPI), according to one embodiments of the disclosure. In some embodiments, the distributed network system 100 can comprise host based systems, for example, a server or a client machine, and in other embodiments, the distributed network system 100 can comprise network based systems, for example, router. The distributed network system 100 comprises a front-end processor 102 and a back end processor 104. In some embodiments, the front-end processor 102 in the distributed network system 100 enables to perform deep packet inspection (DPI) of incoming network data in order to find, identify, classify, reroute or block data packets with specific data or code payloads. In some embodiments, the DPI methodologies are used to match packet data with a database of signatures, a predefined pattern that defines an attack.

In some embodiments, the front-end processor 102 comprises a first network interface circuit 106 configured to receive the network traffic, a network processor circuit 107 configured to process the incoming network traffic and a second network interface circuit 110 configured to forward the processed network traffic to the back-end processor 104 for further processing, based on the processing result at the network processor circuit 107. In some embodiments, the front-end processor 102 can have bi-directional data transfer, where data (i.e., network traffic) from the back-end processor 104 can further flow from the second network interface circuit 110 to the first network interface circuit 106. In such embodiments, the network processor circuit 107 is configured to process the data coming from both the directions. In some embodiments, the network processor circuit 107 comprises a signature matching circuit/system 108 configured to store a database of signatures and compare the incoming network data with the database of signatures, in order to perform the DPI. In some embodiments, based on the result of the DPI, the front-end processor 102 comprising the network processor circuit 107 can take an informed decision on whether to forward the incoming data traffic to the back-end processor 104 for further processing or to be dropped. In some embodiments, the signature matching hardware accelerator system 108 is configured to match the incoming network traffic (e.g., transport layer data) with a deterministic finite automata (DFA) comprising a state table representing the database of signatures, in order to perform the deep packet inspection.

In some embodiments, the first network interface circuit 106 can comprise a plurality of network interfaces or ports, with data transfer between one or more network interfaces in the plurality of network interfaces. In some embodiments, the ports are capable of accepting and sending network traffic. In such embodiments, the network processor 107 comprising the signature matching hardware system 108 is configured to receive the network traffic from one of the ports of the first network interface circuit 106 and perform DPI on the received network traffic, before forwarding the network traffic to a subsequent port within the first network interface circuit 106 or second network interface circuit 110.

In some embodiments, a decision whether to forward the network traffic or drop the network traffic is determined by the network processor 107, based on the result of the DPI. Similarly, in some embodiments, the second network interface circuit 110 can include a plurality of network interfaces or ports, with data transfer between one or more network interfaces in the plurality of network interfaces. In such embodiments, the network processor 107 including accelerated signature matching hardware system 108, is configured to receive the network traffic from one of the ports of the second network interface circuit 110 and perform DPI on the received network traffic, before forwarding the network traffic to a subsequent port within the second network interface circuit 110 or the first network interface circuit 106.

FIG. 1b depicts an example hardware circuit 150 adapted to perform deep packet inspection in distributed networks, according to one embodiment of the disclosure. In some embodiments, DPI circuit 150 is included within the accelerated signature matching module 108 of FIG. 1a. In some embodiments, DPI circuit 150 is configured to store a database of signatures and compare an incoming network data with the database of signatures in order to find, identify, classify, reroute or block data packets with specific data or code. DPI circuit 150 is configured to compare data packets of incoming network traffic with a deterministic finite automaton (DFA) which may comprise a state table representing the database of signatures. DPI circuit 150 may include a processing circuit 152 and a memory circuit 154. In some embodiments, DPI circuit 150 is configured to operate in two phases: a compression phase and a fetch phase.

In the compression phase, the processing circuit 152 is configured to compress an original DFA table comprising a plurality of next state transitions to form a compressed DFA table. In some embodiments, the number of next state transitions in the compressed DFA table is less than the number of next state transitions in the original DFA table. In some embodiments, the original DFA table is compressed to form the compressed DFA table in order to reduce the memory requirement of the DFA and to enable an efficient lookup of the DFA table during deep packet inspection (DPI). In some embodiments, the original DFA table may be compressed to form the compressed DFA table based using a bitmap-based compression technique and additionally, optionally, using an alphabet compression technique, as explained in detail in embodiments described below.

The memory circuit 154 is coupled to the processing circuit 152 and is configured to store the compressed DFA from the processing circuit 152. In some embodiments, the memory circuit can comprise a plurality of lookup tables configured to store the information related to the compressed DFA. In some embodiments, the compression phase is performed within the processing circuit 152 prior to the fetch phase. However, in other embodiments, the compression phase can be performed by a compression processing circuit (not separately shown) external to the DPI circuit 150 and stored in the memory circuit 154 prior to the fetch phase. In some embodiments, the compression processing circuit can be part of the network processor 107 in FIG. 1a, while in other embodiments; the compression processing circuit can be a separate circuit or system on a chip (SoC) external to the network processor 107. It is also possible the original DFA state table and/or the compressed DFA state table may be provided to be used by DFA processing circuit from a separate source, local or external to the network interface card/circuit 100, by example, from an content aware application provider update file such as a virus definition update or the like.

In a fetch phase, the processing circuit 152 is configured to receive a current state and a current input character, and fetch the next state transition corresponding to the current state and the current input character from the compressed DFA stored in the memory circuit 154. In some embodiments, the next state transition for the current state is obtained by fetching information from one or more lookup tables in the memory circuit 154, in accordance with a predetermined algorithm, explained in detail in subsequent embodiments below. In some embodiments, the fetch phase enables the signature matching system 150 to compare bytes of an incoming packet stream with the database of signatures to perform deep packet inspection.

In some embodiments, the signature matching system 108 can comprise one or more hardware accelerator circuits (not shown), each having a compressed DFA state table representing a database of signatures associated therewith. In some embodiments, the one or more hardware accelerator circuits can comprise DFAs with the same signature set for parallel inspection, thereby greatly increasing the throughput of DPI.

Bitmap-Based Transition Compression

Bitmap-based compression is a two dimensional transition compression technique that compresses redundant transitions in an automaton. Example embodiments of bitmap-based DFA compression in DPI may be found in U.S. application Ser. No. 15/199,210, entitled HARDWARE ACCELERATION ARCHITECTURE FOR SIGNATURE MATCHING APPLICATIONS FOR DEEP PACKET INSPECTION, filed on Jun. 30, 2016, and which is fully incorporated by its reference.

Transition Compression

The bit-map transition compression of certain embodiments may involve three general steps that include: (i) intra-state compression, (ii) transition state grouping; and (iii) inter-state compression. As part of the intra-state compression, identical transitions that are adjacent to each other in all the states are compressed through bitmaps along the character axis. After the intra-state compression, the states are clustered into groups using the divide and conquer state grouping algorithm. After grouping the states into subsets of states, a leader state is identified for each group while the rest of the states are called the member states. After the state grouping, one of the state in each group is made the leader state/the reference state, while the other states are called the member states. The state transitions between the leader and the member states are compared at each unique transitions index.

For inter-state compression, those transitions in the member states that are identical to that of the leader state at each unique transition index are compressed. A Member Transition Bitmask (MTB) for each member state identifies the indices at which the transitions in it are compressed. The MTB for a member state is composed of a sequence of single mask bits, where each bit corresponds to the unique transition index. If the member and leader transitions are identical at the unique transition index, then the bitmask bit corresponding to the index is marked ‘0’ in the MTB. If not, the bitmask bit for the index is marked ‘1’ in the MTB.

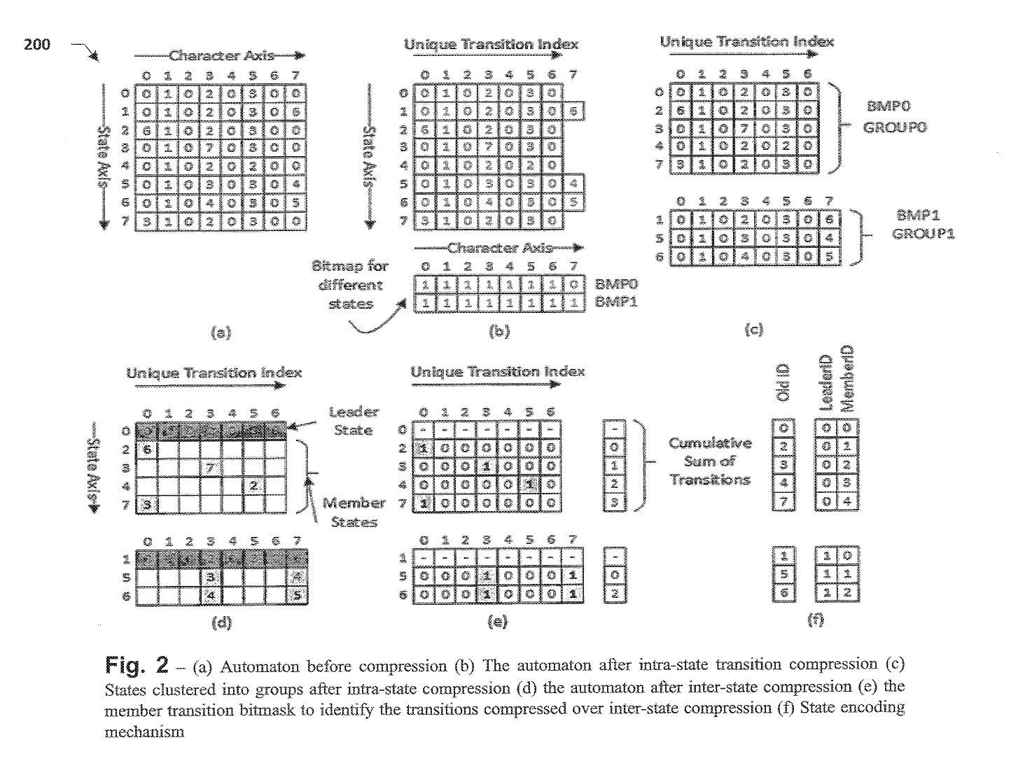

FIG. 2(a) shows a DFA 200 before the transition compression while FIGS. 2(b) and (c) show the DFA 210 after the intra-state compression and the state grouping step. The states with a different bitmap are highlighted in FIG. 2(d). FIG. 2(e) shows the MTB for each member state in a group along with the cumulative transition count. FIG. 2(f) shows the compressed transitions after the inter-state compression step.

For example, the bitmask bit at index ‘0’ for state ‘2’ has a ‘1’, representing that the member transition at the index is different from the leader transition at the same index. On the other hand, the bitmask bit at index ‘3’ for the state ‘2’ has a ‘0’, representing that the member transition at the index is the same as the leader transition at the same index. The transitions which are shown in FIG. 2(d) are the ones that are stored in memory after implementing the bit-map based transition compression. The cumulative sum of transitions is stored together with the MTB to identify the relative number of member transitions stored in memory until the current member state from the first member transition in the group. In the bitmap compression of certain embodiments, the states are encoded and represented as a combination of leaderID and memberID. FIG. 2(f), shows the state encoding between the two representations. The leaderID identifies the group to which a state belongs to and the memberID identifies the member representation within a group of states. The memberID for the leader state is always kept ‘0’ to easily differentiate between a leader state and other member states.

Compressed Transition Data Storage

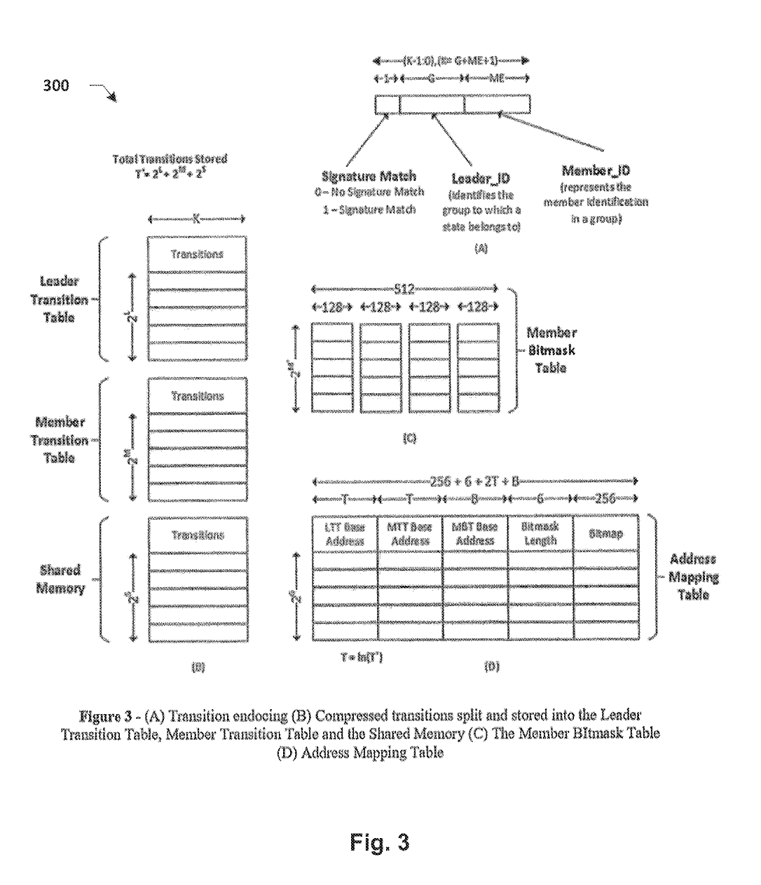

After the bit-map based transition compression, the compressed transitions are stored along with the control information that is required to identify the compressed transition. The memories in which the compressed data is stored are broadly classified into the transition memory and the control memory. The transition memory stores the compressed transitions while the control memories store control information such as bitmaps, bitmasks and base addresses that help to identify the compressed transition, corresponding to the state-character combination. FIGS. 3(A)-(D) provide a general overview one example embodiment of what data is stored and how that data is stored in memory for transition decompression although the inventive embodiments are in no way limited to any specific configuration or classification as suitable alternatives will be realized by those familiar with circuit/memory/software design.

FIG. 3(A) shows automaton state encoding after the bitmap based compression where each state is encoded as a combination of the LeaderID and the MemberID. The automaton state is represented using ‘K’ bits that is split into ‘G’ bits to represent the LeaderID, ‘ME’ bits to represent the MemberID and a single bit to identify the signature match. The signature match bit is set to ‘1’ for those states which, when reached, identify a signature match and is set to ‘0’ for all other states. The states that identify a signature match are referred to as the accepting states and are a subset of states among all the states in an automaton.

As shown in FIG. 3(B), the transition memory may be categorized into the Leader Transition Table (LTT), the Member Transition Table (MTT) and the Shared Memory (SM). Each of these memories store one compressed transition per address location. The LTT stores only the compressed transitions belonging to the leader state (after the intra-state compression) across all the groups. The MTT only stores the compressed transitions from the member state (after the inter-state compression) across all the groups. In one embodiment, the SM is a configurable portion of memory which can be assigned either to the LTT or the MTT to extend the number transitions that can be stored in LTT/MTT. The SM may be made up of small pieces of multiple individual memories allocated to the LTT/MTT. In one embodiment, the assignment of SM to either the LTT or the MTT may be determined during the compression stage, e.g., by a compiler. In various embodiments, the compression accelerator circuit/logic is configured in the runtime based on the partition information generated during compilation and may be programmable through registers. In certain embodiments, an overall total of T′ (2L+2M+2S) transitions are available to be stored in the memory although the inventive embodiments are not limited to any size of storage or memory capabilities.

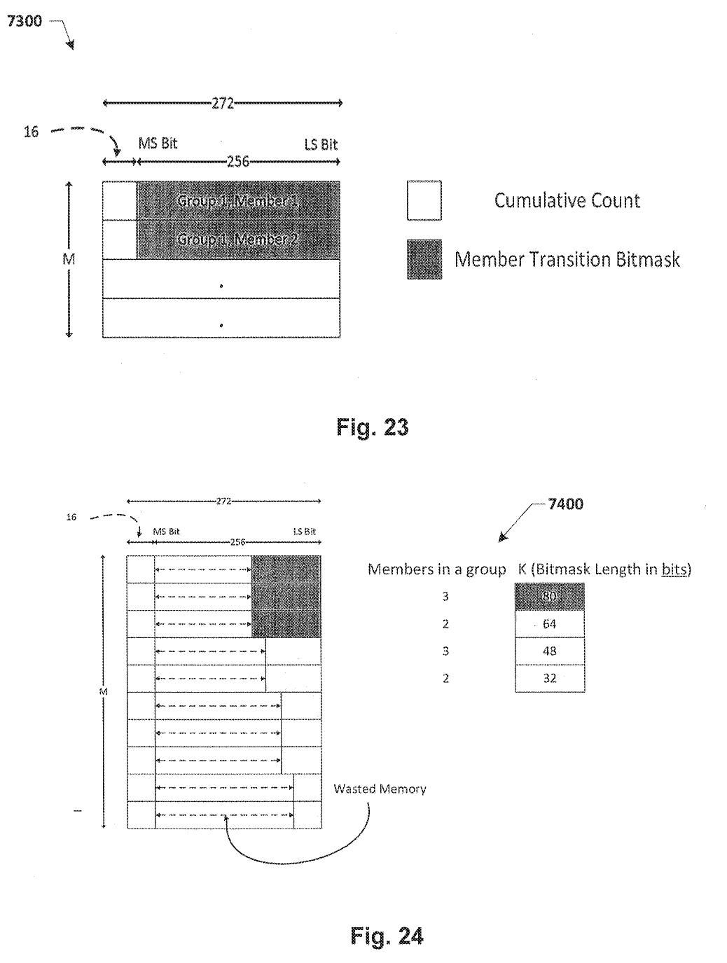

The member transition bitmask (MTB) and the cumulative transition count (also, may be collectively referred to as ‘bitmask’ herein) are stored in the Member Bitmask Table (MBT), and example of which is shown in FIG. 3(C). The MTBs are highly non-linear and their width varies depending on the signature set. A simple sequential memory storage mechanism to store the bitmasks can therefore result in considerable memory wastage. This can be somewhat reduced by storing the bitmasks consecutively in the physical memory. The width of the bitmask to be fetched from the memory is known prior to the bitmask fetch that enables the correct data to be fetched from the memory. If the bitmasks are consecutively stored in physical memory, certain bitmasks can be stored across multiple physical memory locations. Accordingly, in some optional embodiments, the physical memory may be partitioned vertically as shown in FIG. 3(C) to fetch the bitmask in a single clock cycle as discussed in greater detail below and reference to FIGS. 23-31. The value for M′ (for 2^{M} address rows) may be selected depending on the number of states (i.e., number of signatures to be stored) for which a bitmask should be stored.

FIG. 3(D) shows an example “Address Mapping Table (AMT)” which stores control information such as the base addresses, the bitmap and the extended bitmask length for all the groups. The AMT stores the base address of the first data in the group (transition/bitmask) to be fetched from the other memories, i.e. the LTT, the MTT and the MBT. The AMT may also store the bitmap and the extended bitmask length for each group. The bitmap and the extended bitmask length is common for all the states in a group and only needs to be stored once. As part of the transition decompression, the base address to retrieve the data from the other memories (LTT/MTT & MBT) is fetched from the AMT and the offset address is calculated from the control information such as the bitmap and the bitmask. The base address when added together with the computed offset address provides the precise location of the compressed transition. The “Address Mapping Table” and the “Member Bitmask Table” are categorized into the control memories while the Leader and the Member transition tables may be categorized into the transition memories.

Signature Matching

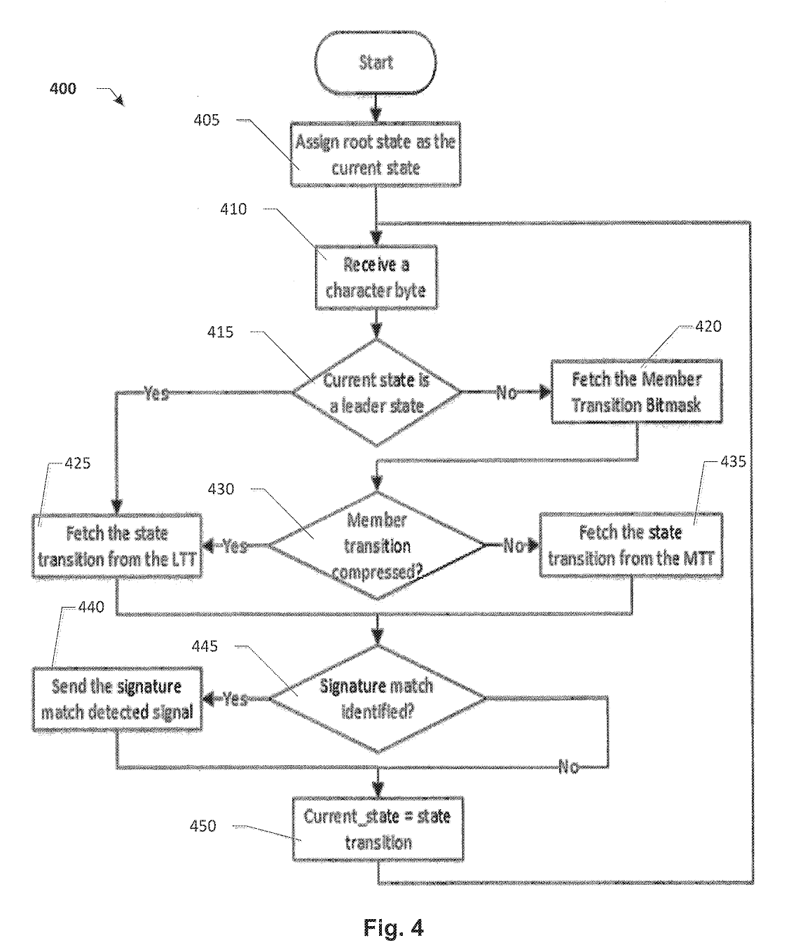

Referring to FIG. 4, a method 400 for DPI signature matching according to one embodiment is shown. A key function of a signature matching is to scan the network payload bytes against the automaton. The process 400 starts with the root state (the initial state from which the state transition fetch starts) of the automaton being assigned 405 as the current state. Corresponding to the current state 405 and the payload byte 410 combination 420, a next state transition is fetched 425 or 435 from the memory. If 445 the identified next state belongs to the set of accepting states, a signature match is identified 445 and a signature detect signal is generated 430. When 430 the state transition that is fetched is one among the compressed transitions generated after MSBT transition compression, it is fetched 425 from the leader transition table (LTT). Otherwise, the transition is fetched 435 from the member transition table (MTT).

Specifically, if 415 the memberID corresponding to the state transition representation is “0”, then the current state is a leader state and the state transition is fetched from the LTT. On the other hand, if the current state is a member state, the member table bitmask (MTB) is fetched 420 from the memory and examined first to identify 430 if the state transition was compressed as part of the inter-state compression in MSBT. If the state transition corresponding to the incoming character is compressed, then the state transition is fetched 425 from the LTT. If the state transition corresponding to the incoming character is not compressed, then the state transition is fetched 435 from the MTT. If 445 the signature match bit in the state transition is 1, a signature match detection signal is generated 440. The state transition is assigned 450 as the current state to continue the same process with the next payload byte and is a continuous process.

Bitmap Decompression Engine and Transition Decompression

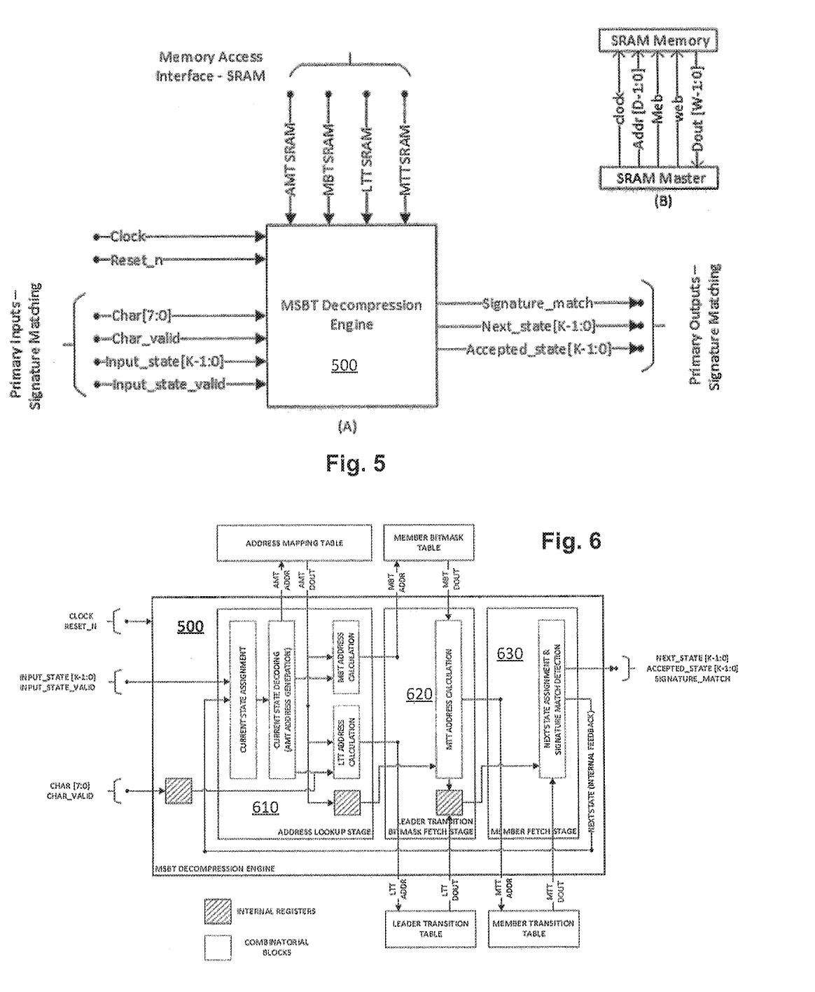

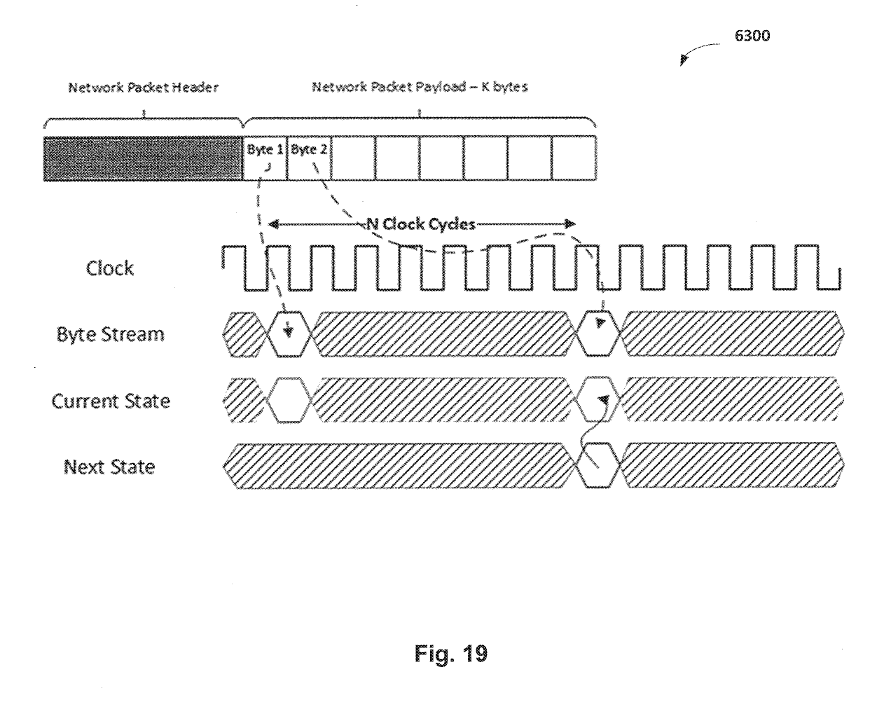

FIG. 5 (A) shows the top level architecture of a DFA decompression engine 500 according to one embodiment. The decompression engine 500 has a set of primary inputs and outputs. The primary inputs to the engine are the character (payload byte−8 bits/clock cycle) and the input state signal with a corresponding valid signal to latch them. In one embodiment, the network payload from multiple contexts (discussed later in reference to FIGS. 19-22 are split into individual bytes and are interleaved before being sent to the engine every clock cycle. The input state is either the state at which the signature matching is started initially or resumed from during context switching. Based on the state-character (byte) combination, a next state transition is fetched from the compressed state transitions. The primary outputs from the engine 500 are the next state transition, a signature match (detection) signal and the corresponding accepting state to identify the specific signature that matched the byte stream. During the transition decompression, the transition and the control memories are accessed through the SRAM interface. A pictorial description of the SRAM interface is shown in FIG. 5(B). The decompression engine 500, which may include the SRAM Master interface, provides the clock, the memory enable (Meb), the write enable (web) and the address location while the memory provides the data corresponding to the address location. It should be noted that the DFA decompression engine 500 preferably, may only read the data from the memory and does not write into the memories. All the memories and the registers are driven by the clock signal shown in FIG. 5 and are not necessarily explicitly shown in simplified drawing figures.

FIG. 6 shows the internal block level architecture of the DFA decompression engine. The decompression engine 500 comprises three internal blocks. The first block is called the Address Lookup Stage (ALS) 610. This block consists of the logic to assign the current state so that the transition decompression corresponding to the character-state combination is initiated. Then the current state is decoded to identify the leaderID and the memberID corresponding to the state transition. In the ALS 610, the leaderID is used as the address to fetch the data (base address for the transition fetch, the bitmask fetch, the bitmap and the extended bitmask length) from the AMT. Once the base address is fetched, an offset address is computed and added together with the base address to calculate the precise memory location for the leader transition table (LTT) and the member bitmask table (MBT). The LTT and the MBT addresses may be calculated using the following Equations (1) and (2):

LTT_Address=LTT_Base_Address+PopCount(Bitmap) (1)

MBT_Address=MBT_Base_Address+(MemberID*Extended Bitmask Length) (2)

LTT_Address represents the address location from which the transition corresponding to the character in the group's leader state. The transition fetched from the LTT_Address is called the leader transition. MBT address represents the start address location from which the MTB and the cumulative transition count are fetched. The circuits calculating in Equations 1 and 2 may reside in the blocks “LTT Address Calculation” and “MBT Address Calculation” respectively.

The actual data fetch from the LTT and the MBT are performed in the Leader Transition Bitmask Fetch Stage (LTBFS) 620. Based on the data fetched from the MBT, the address of the transition to be fetched from the MTT is calculated in the LTBFS 620, but the leader transition is fetched from this address location only in the case of the current state being a member state or the transition to be fetched is not compressed during the inter-state compression. An example embodiment of a hardware circuit that calculates the MTT address is shown in the “MTT Address calculation” block in the LTBFS and can be determined using Equation (3):

MTT_Address=MTT_Base_Address+Cumulative Transition Count+PopCount(MTB) (3)

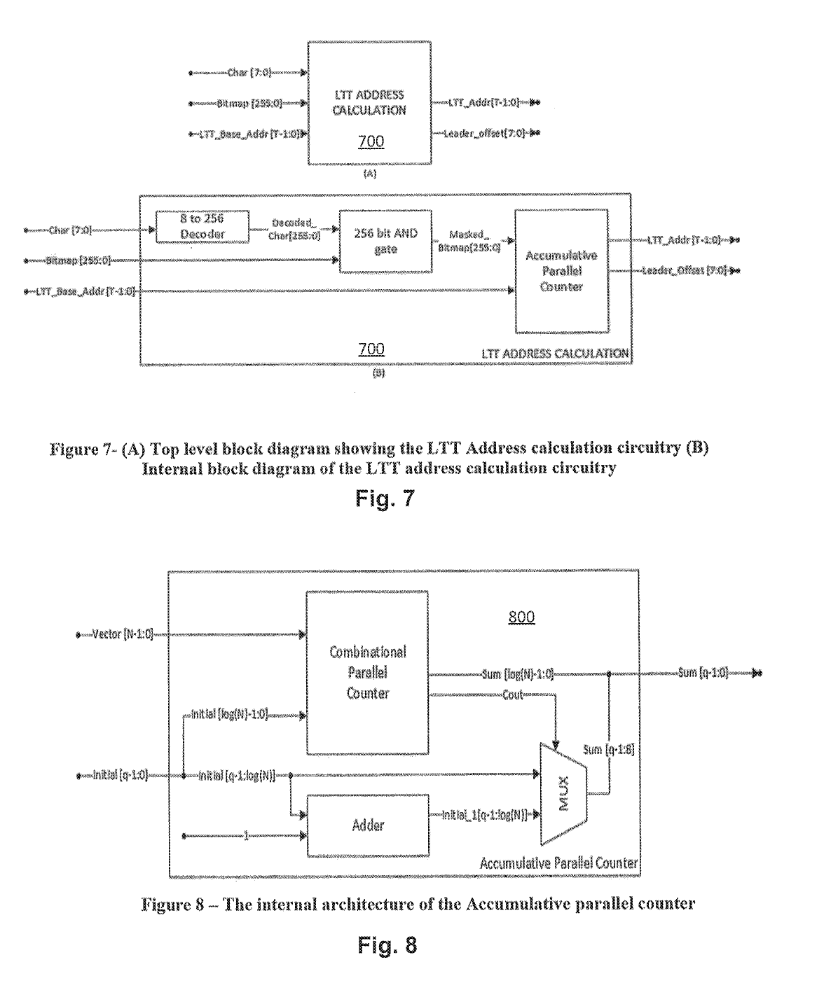

Finally, once the address is calculated, the data from the MTT is fetched in the Member Fetch Stage (MFS) 630. The data fetched from the MTT is called the member transition and the next state is assigned either from the leader or the member transitions. A signature match is identified from the signature match bit in the compressed transition. The above-mentioned functions may be performed in the MFS 630 as shown in FIG. 6 and detailed circuitry in each block is shown and described in relation to FIGS. 7-10.

Internal Micro-Architecture of the Hardware Accelerator

LTT Address Calculation Circuitry is shown in FIGS. 7(A) and (B). FIG. 7(A) shows the block diagram of the circuitry that is used to calculate the address of the transition to be fetched from the LTT. As shown in 7(A), the LTT base address and the bitmap, fetched from the AMT and the payload byte are the inputs which are required for the LTT address calculation. The circuitry shown in the figure generates the address location from which the leader transition is fetched and generates the leader offset in which the MTB is examined.

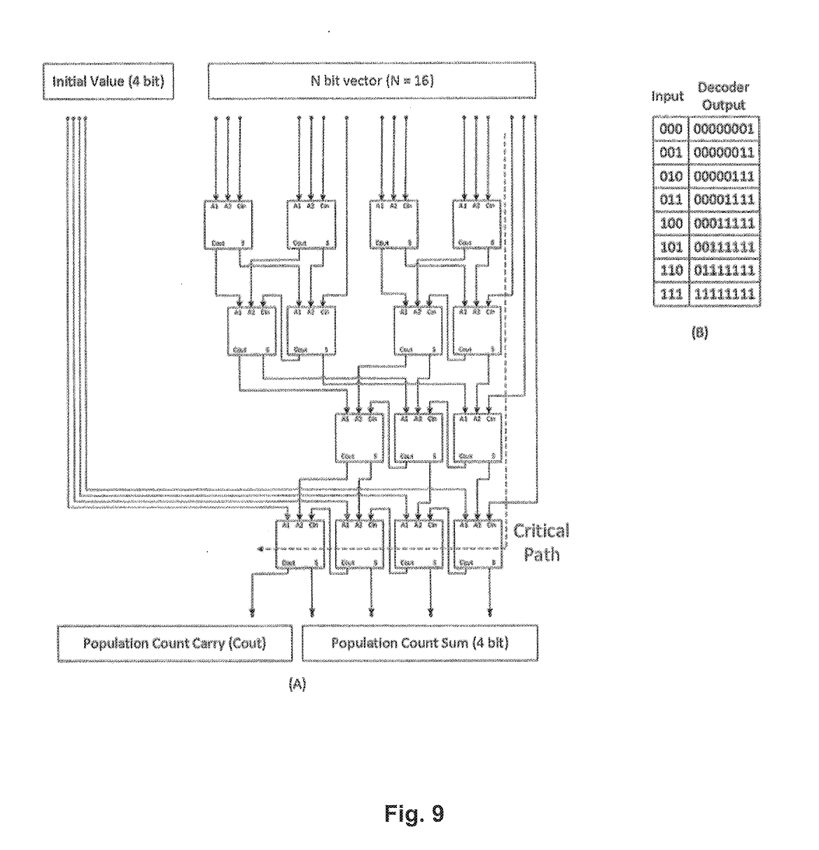

The address of the transition which is fetched from the LTT is calculated by adding the LTT base address with an offset address. The offset address is calculated by performing a population count operation on the bitmap. The bits which are irrelevant for the offset address calculation are masked in the bitmap. A mask is generated using an 8 to 256 bit decoder circuit to which the payload byte is an input. An example of the decoder function is shown in FIG. 9(B). The decoder sets ‘0’ to all the bits from the most significant bit position until the bit position of interest. A simple ‘AND’ operation is performed on the bitmap together with the mask generated by the decoder. In this way, the population count is performed only on the specific bits of interest in the bitmap.

The address computation is performed by the accumulative parallel counter (APC) circuit 800 as shown in FIG. 8. The APC circuit 800 has two inputs, a sequence of N-bit vector and a q-bit initial value. The APC circuit 800 counts the number of l's in the N-bit vector and adds this value to the q-bit initial number. The population count (a.k.a. the hamming weight) is performed using the parallel counter circuit. The APC 800 takes the N bit vector and the lower log₂(N) bits out of the q bit initial value as inputs to produce a log₂(N) bit sum and a single bit carry. The log₂(N) bit sum value forms the least significant bits of the APC sum output while the higher q-log(N) bits are calculated by multiplexing the higher q-log₂(N) bits or 1 added to the q-log₂(N) bits. The multiplexing operation makes sure that the higher q-log₂(N) bits are set appropriately in case of an overflow detected in the parallel counter. The addition operation maybe performed in the hardware using carry save adders (built using 4 bit carry look ahead adders) to keep the latency minimal. The masked bitmap is connected to the N-bit vector while the LTT base address is connected to the q-bit initial value. The leader offset and the LTT address are the outputs produced by this circuit.

As mentioned earlier, the parallel counter 800 performs the population count function. It consists of a tree of increasing wider ripple carry adders. The first level consists of log 2(N) full adders while the last level includes a single log 2(N) wide ripple carry adder. The worst case latency of the parallel adder circuit is 2×log 2(N)−1 full adder delays.

FIG. 9 (A) shows an example of the parallel adder circuit 900 for N set to ‘16’ together with a 4-bit initial value. The circuit finally outputs a 4-bit sum with a single bit carry which detects an overflow in the addition operation. As mentioned earlier, example of the decoder function is shown in FIG. 9(B). The decoder sets ‘0’ to all the bits from the most significant bit position until the bit position of interest. A simple ‘AND’ operation is performed on the bitmap together with the mask generated by the decoder.

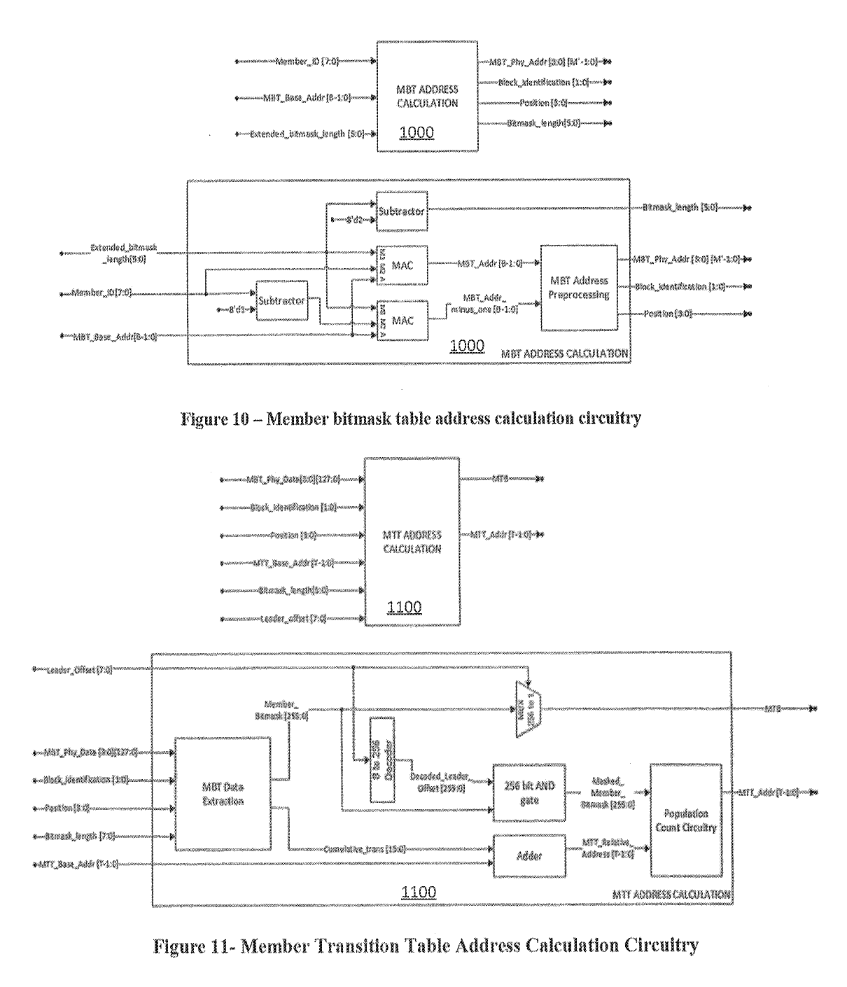

FIG. 10 shows the MBT Address calculation circuitry 1000 to calculate the address location of the bitmask. The extended bitmask length, the MBT base address fetched from the AMT and the memberID are the primary inputs used by this circuit. The extended bitmask length that is stored in the AMT is actually two added to the bitmask length to accommodate the 2-byte cumulative transition count stored along with each MTB. This is multiplied with the memberID and then added to the base address to generate the address location for the member bitmask. The above mentioned calculations are performed using a multiplier accumulator (MAC) in the hardware. The multiplicand and the multiplier are 8-bits and 6-bits respectively and, in one example embodiment, the MAC circuit is implemented using a Wallace tree construction to keep the latency minimal.

In various example embodiments, a Packed Storage Architecture (PSA) may be used to store the bitmasks that requires two addresses to fetch the data from the member bitmask table (as explained in greater detail with reference to FIGS. 23-31). In worst case scenarios, the bitmask is split across two different physical memory address locations, e.g., an address location (e.g. B′) and its predecessor (B′−1). This is a potential downside in storing the bitmasks in continuous physical addresses using the PSA. A simple way to calculate the predecessor address (B′−1) is to subtract one from the calculated physical address (B′). However, this may increase latency of the address generation circuitry and may affect the performance of the design. Alternatively, the previous physical address location may be identified by multiplying the extended bitmask length with memberID-1. This generates the start address location of the bitmask corresponding to one member state before the current state. If the bitmask for the member state is spread across two physical address locations, the example embodiment will be able to compute the physical address of the predecessor (B′−1) in parallel to the standard bitmask address location. If the bitmask is not spread across multiple physical address locations, of course this information is unnecessary and the data fetched from the memory simply goes unused. In this manner, the address computation may be done in parallel to keep the latency low and achieve an improved performance design.

The circuitry which performs the subtraction will generate the memberID-1 before the data from the AMT is available for further computation. An MBT address pre-processing block in one embodiment, generates the physical address location for the four physical memories together with the block identification and the position bits. The next stage that extracts the member bitmask from the data fetched from the memory requires the bitmask length. A subtraction circuit subtracts ‘d2 from the extended bitmask length and will generate the bitmask length which is used to extract the MTB from the data fetched from the memory. In one example embodiment, the subtraction circuits are implemented as carry save adders where the corresponding data is added with [8′b11111111 (−1 for memberID)] and [8′b11111110 (−2 for extended bitmask length)].

Referring to FIG. 11, an example embodiment for MTT address calculation circuitry 1100 may be very similar to that of the LTT address calculation circuitry of FIG. 7 described previously. The inputs to the block are the data fetched from the member bitmask table along with various outputs generated by the MBT and the LTT address calculation circuitries such as the block identification, position, bitmask length and the leader offset. The MTT base address is also provided as an input to this block. The non-memory input signals are registered appropriately to maintain the integrity of the pipeline.

The primary outputs of this block are the address location from which the member transition is fetched and the MTB corresponding to the leader offset position. The 256-bit member bitmask and the cumulative transition information are extracted from the data fetched from the member bitmask table.

There are two primary functions performed by this circuit 1100. The first function is the member bitmask identification corresponding to the leader offset (identifies the unique transition index). A 256-to-1 multiplexer is used to multiplex the MTB bit corresponding to the leader offset position (a.k.a. unique transition index). The output of the multiplexer detects whether the transition corresponding to the unique transition index is compressed or not compressed during the inter-state compression. The output of the multiplexer assigns the next state accordingly in the case of current state being a member state. In certain example embodiments, the multiplexer may be implemented in a hierarchical fashion using a group of smaller multiplexers (e.g., 8-to-1 and/or 4-to-1 multiplexers).

The second primary function is the calculation of the address location from which the transition is fetched from the MTT. As mentioned, the address computation circuitry is very similar to that of the LTT address computation circuitry previously described. The MTT base address fetched from the AMT (after being registered) is first added to the cumulative transition count fetched from the member bitmask table (MBT). The addition operation is performed using a carry save adder similar to the one discussed in the LTT circuitry. The base address added to the cumulative transition count produces the relative address of the transition among the member transitions stored in memory until the current state. A decoder similar to the one used in the LTT address calculation may be used to calculate the offset address of the compressed transition within the member state. The masked MTB is sent to the population count bock to identify the offset address of the transition among the compressed transitions in the member state. The previously calculated relative address with the cumulative transition count and the base address is added to the one calculated from the bitmask in the population count circuitry.

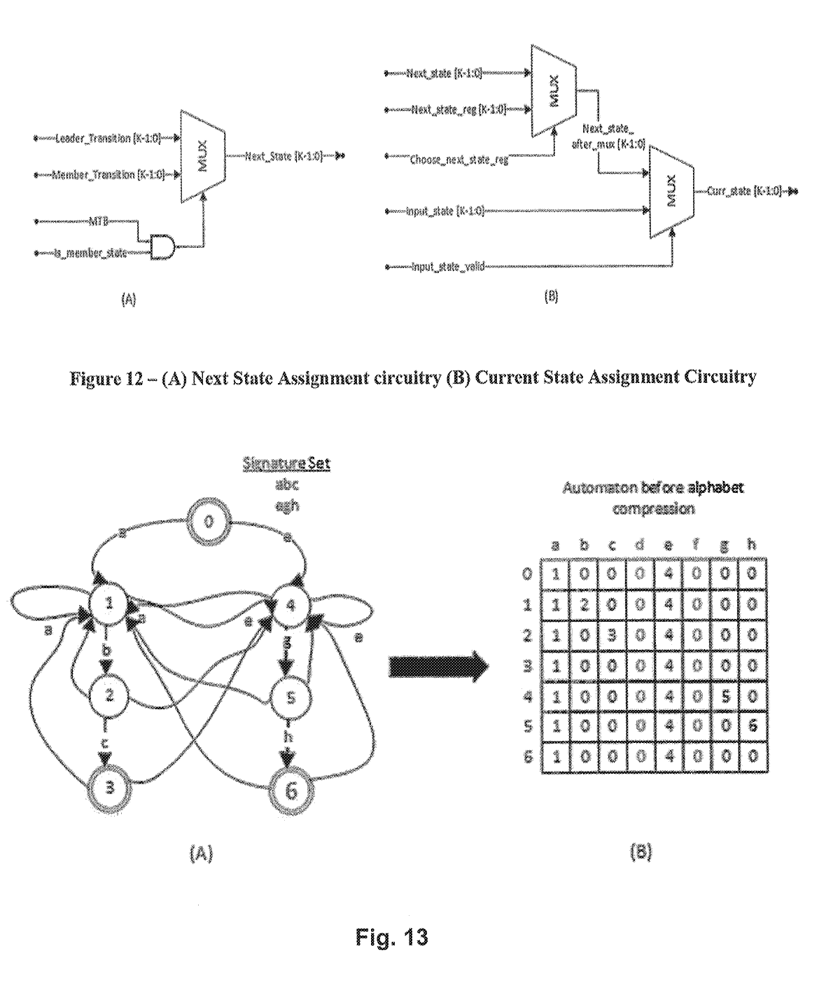

Once the leader and the member transitions are fetched from the corresponding memories, the next state is assigned using Next State and Current State Assignment Circuitry as shown in FIGS. 12(A) and 12(B). FIG. 12(A) shows circuitry for the next state assignment while FIG. 12 (B) shows the circuitry for the current state assignment.

In FIG. 12(A), a combination of the MTB calculated at the leader offset position (represented as MTB), and a signal which identifies the current state as a member state are used to decide the next state assignment. If the current state is a leader state, the transition fetched from the LTT (leader transition) is directly assigned as the next state transition. On the other hand, if the current state is a member state, then the MTB decides the next state transition. If the MTB corresponding to the calculated transition index position is ‘1’, then the transition fetched from the MTT (i.e., member transition) is assigned as the next state while the leader transition is assigned if it is not. A signature match is detected, if the most significant bit in the identified next state transition=‘1’. In such a case, the accepted state is set to the same value as the next state which will identify the exact signature that was matched in the byte stream.

FIG. 12(B) details the current state assignment based on various scenarios. The interface which provides the byte stream informs the DFA signature matching engine the state with which state the signature matching function starts. This is done to provide the engine with the root state, which is the very first state from which the signature matching function indicates. In one example embodiment, a context switch may be included during signature matching, the same interface provides the state information with which the signature matching is resumed. The state from which the signature matching starts is sent through the input state signal together with the input state valid signal as shown in FIG. 12(B).

On the other hand, when there is a consecutive stream of bytes in a packet stream, the next state is directly assigned to the current state, once it is available. However, if there is a break in the stream of bytes corresponding to a stream, the next state is internally registered on a per context basis and assigned as the current state whenever the byte stream restarts. The input state signal should have precedence over other other scenarios.

The foregoing hardware architecture was designed using Verilog RTL and synthesized on a TSMC 28HPC+ technology library to validate results. The modeled signature matching DFA engine was architected to store a maximum of 64K states. In simulation, it took 3 clock cycles (3 pipeline stages) to fetch the compressed transition corresponding to the current state-payload byte combination. In order to improve the throughput of the system, additional registers were added in the combinatorial paths in the logic that calculates the address for MBT, LTT and the MTT. For example, a single register stage was added in MBT and LTT while two register stages were added in the MTT address calculation block. Table reflects overall simulation results of the DPI hardware acceleration engine described herein using two different configurations as shown in Table 1. The “basic pipeline” implementation consisted of 3 pipeline stages, 1 for each of the processing stages (ALS, LTBFS and the MFS) whereas the “advanced pipeline” implementation consisted of 6 pipeline stages in total, with the additional registers added in the combinatorial path. The basic pipeline implementation achieved a clock frequency of about ˜700 Mhz enabling a signature matching throughput of 5.5 Gbps. The advanced pipeline implementation achieved a clock frequency of about 1.150 GHz translating to a signature matching throughput of ˜9.5 Gbps. The signature matching engine pipeline was continually fed by interleaving payload bytes from multiple contexts (streams).

TABLE 1
Simulated Results

| | Basic | Advanced |
|---|---|---|
| | Pipeline | Pipeline |
| Throughput | | |
| Achievable Frequency (MHz) | 690 | 1165 |
| Throughput (Mbps) | 5520 | 9320 |
| # Pipeline Stages | 3 | 6 |
| Maximum Throughput/Stream (Mbps) | 1840 | 1553 |
| Area (u mm²) | | |
| Combo | 22414 | 23247 |
| Sequential | 6294 | 9787 |
| Memory | 1401641 | 1401641 |
| Total Area | 1430349 | 1434675 |

It can also be seen from Table that the on-chip static random access memory (SRAM) dominates the area occupied by the DPI hardware accelerator. The combinatorial and the sequential logic blocks form a very negligible portion of the overall accelerator. Therefore, the introduction of additional registers to improve pipeline performance is a negligible variance in the area size of the accelerator.

Alphabet Compression

As discussed previously, Deep Packet Inspection (DPI) performs signature matching using a specific range or set of possible characters, e.g., the alphanumeric characters. Frequently, certain characters from this character set do not occur in any of the signatures. The state transitions in the automaton resulting from some of these characters cannot be compressed efficiently using bitmap-based transition compression techniques, which results in redundant transitions being stored in memory. According to further embodiments of the invention, these type of redundant transitions may be better and more efficiently compressed by initially applying an alphabet compression process to further accelerate DPI throughput and reduce memory usage when used in subsequent combination with the bitmap-based compression embodiments described previously, and as discussed in example embodiments below.

In certain embodiments, alphabet compression is initially used to compress a signature character set and related redundant transitions for indistinguishable characters in signatures of an automaton. Subsequently, a bitmap compression process, as in any embodiment previously discussed, is applied to achieve better performance than just bitmap compression alone. The following inventive embodiments relate to a combination of alphabet compression and bitmap compression, which result in an even more efficient transition compression rate. These embodiments may be particularly helpful when utilized in end user device such as home gateways, routers, modems or the like, because the reduction in the memory usage and improved ability to perform signature matching at line rates ˜10 Gbps and beyond. Combining alphabet compression and bitmap compression of an automaton in embodiments of the present invention have shown to result in an additional transitions compressed on the order of 5-10% across various signature sets. Modification of the DFA bitmap based compression architectures previously discussed will also be described.

FIGS. 13(A) and 13(B) show an example of a signature set to automata conversion. For example, a set of signature's “abc” and “egh” are shown representing a finite automaton. It is assumed that the characters which the signatures are made up of belongs to the English language alphabet characters {a, b, c, d, e, f, g and h}. FIG. 13(A) represents the finite automaton (or DFA), and FIG. 13(B) represents the signature matching state table corresponding to the automaton. Signature matching starts with the root state (state 0) and a next state is calculated for each state-character combination. The characters for comparison with the automaton are scanned as the sequence of bytes in the packet data payload. If the calculated next state leads to an accepting state (e.g., state 3/6), then a signature match is identified. The transitions which may lead to the root state (failure transitions) are not specifically shown in the automaton representation. Notwithstanding, as can be seen in the state table, there are large number of redundant state transitions which may be compressed using transition compression techniques. In such a scenario, the state table lookup may be performed on the compressed state table representation.

As shown in FIG. 13(B), the state transitions corresponding to the characters ‘d’ and ‘f’ are identical for all the states. From the automaton's perspective, the characters, ‘d’ and ‘f’ are indistinguishable since they lead to the same next state, across all the states. It is these particular transitions that may be compressed more efficiently using alphabet compression than bitmap compression techniques. The aim of alphabet compression in the inventive embodiments pertaining to its use, is to reduce the number of characters in the character set and related transitions of the automaton to which bitmap compression is subsequently applied.

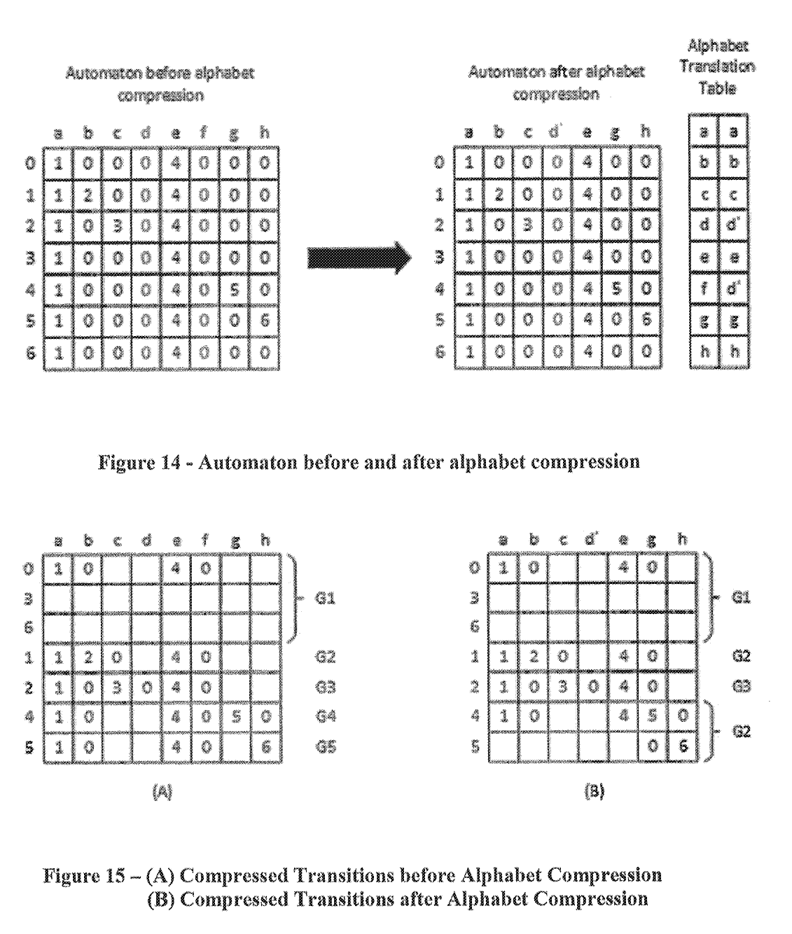

Referring to FIG. 14, an illustrative example of alphabet compression is illustrated. Here, the characters ‘d’ and ‘f’ are combined to create a new character called ‘d’′ (or “d prime”) which modifies the overall signature character set to {a, b, c, d′, e, g and h}. The alphabet compression reduces the number of characters in character set and hence, the number of state transitions in the resulting automaton, which would otherwise include redundant states, even when applying bitmap compression algorithms. For example, the original automaton consists of 7*8=56 transitions while the modified automaton includes only 7*7=49 transitions, as a direct result of alphabet compression reducing the number of characters in a given signature character set. In various embodiments, an alphabet translation table may be created to store the original character set as an alphabet encoded character set representation and subsequent bitmap compression will be applied to less characters/transitions. Thus, in certain embodiments of DPI signature matching, an incoming character may be retrieved from an Alphabet Translation Table (ATT) to identify one or more encoded character representations and further proceed with the signature matching based on the bitmap-based compression processing.

FIGS. 15 (A) and (B) demonstrate the comparison of bitmap compressed automaton with 1520 and without 1510 alphabet compression. FIG. 15(A) illustrates the compressed transitions 1510 when only bitmap-based compression is performed on the automata shown in FIG. 13. FIG. 15(B) shows the compressed transitions 1520 when bitmap compression is performed on the automata after alphabet compression, i.e., from FIG. 14. The state transition corresponding to {4, f=0}¹ is not compressed as part of the intra-state compression in FIG. 15(A), as it is blocked to bitmap compression by the transition corresponding to {4, e=4} which is different from the transition corresponding to {4, d=0}. On the other hand, this scenario doesn't occur in FIG. 15(B), after the characters whose state transitions are indistinguishable, i.e., ‘d’ and ‘f’, are compressed into ‘d” through alphabet compression. Accordingly, it is simple to observe that bitmap-based transition compression performed after alphabet compression, results in an improved transition compression. Explicitly, an additional four transitions are compressed when utilizing the combination of alphabet compression and bitmap compression. ¹A State transition is represented as a combination of the inputs that are the state and the character. For example, the state transition corresponding to character f in state 4 {4, f=0} in FIG. 15A is 0. This format is used to represent a state transition in this disclosure.

Alphabet Compression is an ideal initial compression technique for patterns/signatures used in DPI as ASCII encoding is used to represent Internet traffic, the ASCII character set is also used to represent signatures. This means that a majority of characters belonging to the ASCII character range “128-255”, are generally not used to define signatures, and thus are ideal candidates for alphabet compression because the state transitions corresponding to these characters, among all the states, lead to the root state (failure transitions=non matching signature). Moreover, regular expression signatures may have terms such as character ranges including wildcard terms over character ranges. For example, a signature “abc[d-k]” can match the character sequence a, b and c followed by any character between d-k. In such a case, the state transitions corresponding to characters d-k across all the states will be identical, unless and/or until there is some other signature that uses a specific character between d-k. If there is not, transitions corresponding to these character ranges are mostly identical and can be efficiently initially compressed/simplified using alphabet compression and subsequently bitmap based compression performed on a lessor number of state transitions.

Of course the costs of combining alphabet compression with bitmap-based compression, e.g., memory, processor, clock utilizations, must be considered as well. When bitmap-based transition compression method is combined with alphabet compression, an additional storage cost will be incurred to store the alphabet translation table (ATT). However, this added table is negligible in comparison to the storage savings resulting from the overall improvement in efficiency of transition compression. As an example, if the ATT is composed of 256-entries (all possible ASKII characters), each 8-bits wide to store an encoded character representation after alphabet compression, the theoretical worst case scenario is 8-bits will be needed to represent each encoded compressed character set in a shared memory, 8*256 bits in a dedicated/partitioned memory. As evidenced by the four transitions compressed in the example above, overall storage savings in at least the LTT and MTTs discussed in the architectures earlier, will significantly exceed storage for the added ATT, by virtue of fewer states/transitions to process. Even if not, depending on implementation, 2048 bits of additional memory is insignificant to the performance increase due to the number of transitions in the automaton being less than with bitmap compression alone.

Table 3 below summarizes the simulation results for bitmap-based transition compression performed without and with alphabet compression. The simulations were performed using five different data sets. The first three datasets consisting of (24), (31) and (34) regular expression signatures from a Snort open source intrusion detection system. A majority of signatures in these simulated results include wildcard operators with associate character ranges. On the other hand, “Exact Match” is a set of 500 string and “Bro217” is a set of 217 regular expression signatures extracted from a Bro intrusion detection system.

TABLE 3
Transition Compression Results using without and with Alphabet Compression

| | | | Compressed | Compressed | |
|---|---|---|---|---|---|
| | #Transitions | #Unique characters | Transitions | Transitions | % Difference |
| | w/o any | after alphabet | w/o Alphabet | after Alphabet | in compressed |
| Signature Set | compression | compression | Compression | Compression | transitions |
| Snort24 | 3553792 | 67 | 49300 | 44938 | 9 |
| Snort31 | 4997632 | 77 | 101924 | 93631 | 8 |
| Snort34 | 3541504 | 74 | 49711 | 44228 | 11 |
| Exact_Match | 3878144 | 112 | 36182 | 35055 | 3 |
| Bro217 | 1672448 | 111 | 26117 | 25911 | 1 |

The second column in Table 3 shows the total number transitions in the automaton generated from the signature sets and represents the total number of transitions in an automaton before any compression technique is implemented. It has to be noted that an enormous amount of memory will be required to store all these transitions in the memory which is why the redundant transitions are eliminated using various compression techniques. The fourth column represents the total number of compressed transitions after implementing bitmap-based transition compression on the automaton without alphabet compression. The number of transitions here roughly represents about 1-2% of the total number of transitions in the automaton. The fifth column in Table 3 represents the total number of compressed transitions after alphabet compression and bitmap-based compression in combination. The third column represents the total number of unique characters in the character set after alphabet compression. As mentioned previously, since the original automaton is built on the ASCII character set, the original character set of 256 unique characters, after alphabet compression, and depending on the characteristics of the signature set, demonstrates that a majority of the characters in each set have been significantly reduced. Lastly, the sixth column shows the percentage difference in the number of compressed transitions when between an automaton with and without alphabet compression. An average of about 5-10% reduction in the compressed transition count is the result when bitmap compression is implemented in combination with alphabet compression. As discussed previously, this difference is due to the fact that certain transitions which cannot be compressed by the intra-state bitmap-based compression are more efficiently compressed when combined with alphabet compressed automaton.

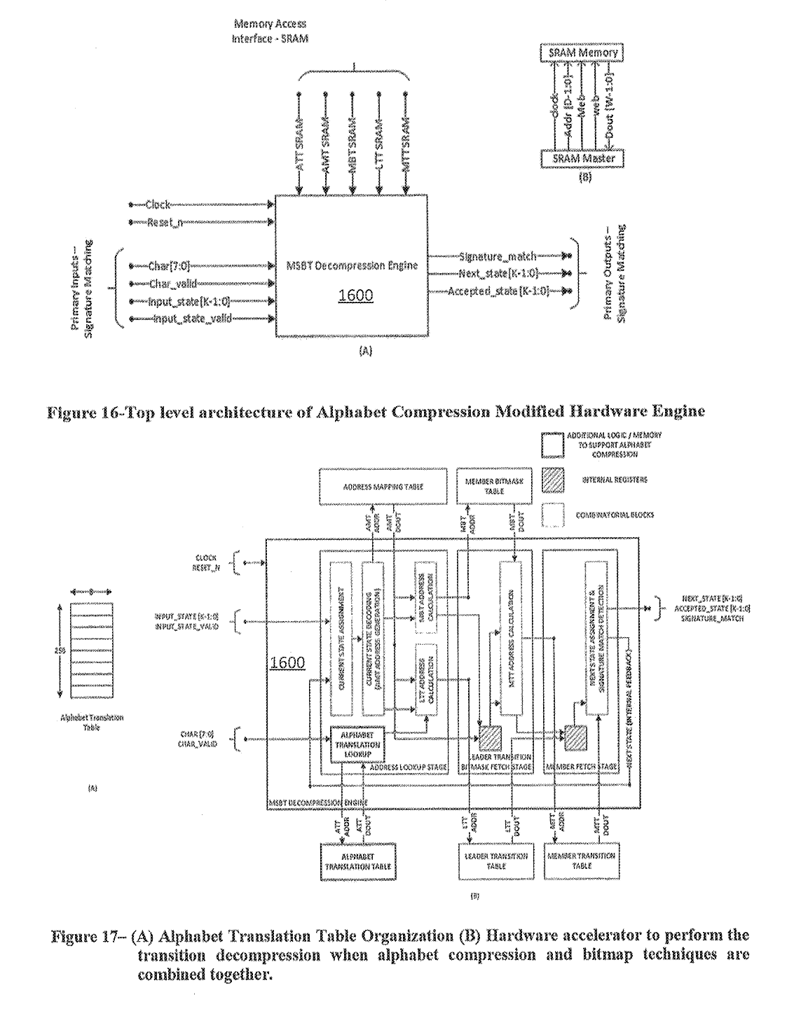

Referring to FIGS. 16 and 17, alphabet compression may be implemented in the bitmap-based compression Hardware Decompression Engine previously described in a relatively simple manner easily. FIG. 16 shows an example embodiment including modified architecture of the decompression engine 1600 utilizing both alphabet compression and bitmap-based compression processes. The decompression engine 1600 comprises of a set of primary inputs and outputs. The primary inputs include the character from the payload byte stream and the input state information at which the signature matching is either started or continued. The primary set of outputs include a set of signals which inform about a signature match and to provide additional information in the case of a signature match. These two interfaces are the same as described previously and will not be explained again here. Essentially, the only difference in the top level architecture is the additional SRAM interface to access the Alphabet Translation Table (ATT). The SRAM interface which is used to fetch the data from the ATT, is similar to that of the other memory interfaces accessing other tables described earlier.

FIG. 17(A) shows the memory representation of the ATT. In one embodiment, the ATT has 256-entries each of which stores an 8-bit encoded data corresponding to each and every character in the ASCII character set after alphabet compression. Therefore, the address for the ATT is the original 8-bit character ASCII encoding of the incoming byte. The encoded representation corresponding to the byte is looked up/fetched from the ATT and used in bitmap-based transition decompression. At this point, the incoming character is registered and used for the LTT address calculation. An example embodiment of block level architecture of a modified hardware accelerator is shown in 17(B) with the new blocks introduced for alphabet compression being shown in dark outlined blocks.

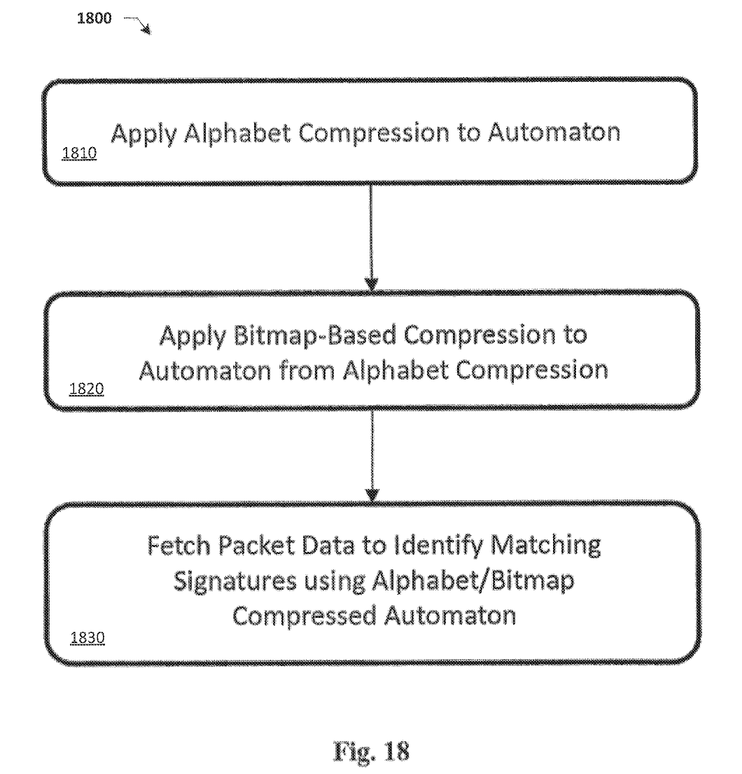

Referring to FIG. 18, a method 1800 for signature mating in deep packet inspection (DPI) using a signature set converted into an automaton comprising a state machine table representation of signature characters of the signature set, as a plurality of state nodes and state transitions, the method comprising: simplifying 1810 the automaton to compress indistinguishable or unused characters of the signature set and their corresponding state transitions using an alphabet compression process to provide an encoded automaton; applying 1820 a bitmap-based compression process on the encoded automaton; and fetching 1830 packet data for comparison the bitmap-based compressed automaton to identify signature matches.

In some embodiments, the bitmap-based compression comprises: performing intra-state compression of redundant adjacent character transitions of the encoded automaton, segmenting the intra-state compressed automaton into groups having matching bitmaps and designating a leader state and one or more member states for each group; and performing inter-state compression of redundant transitions of member states for each group.

Example embodiments of alphabet compressed and bitmap-based compression of DFA include:

In a First example embodiment, a device is disclosed for signature matching using deep packet inspection (DPI) to detect content aware application in incoming packets of a communications network using deterministic finite automata (DFA) representing signatures to be matched, the device including: a leader-state transition table (LTT) memory; a member-state transition table (MTT) memory; an alphabet transition table (ATT) memory; and DPI processing circuitry coupled to said memories, the DPI processing circuit configured to perform an alphabet compression process on the DFA to simplify indistinguishable characters and corresponding state transitions into an encoded DFA representation to store in the ATT memory, and to perform a bitmap compression process on the encoded DFA representation to reduce redundant state transitions and store in the LTT and MTT memories.

A Second example further defines the First example by including data fetch circuitry coupled to the DPI processing circuit to apply packet data to the alphabet and bitmap compressed DFA and identify matching signatures.

In a Third example embodiment, the First or Second may be further defined wherein the ATT memory is configured to store 256 encoded DFA entries, each entry being 8-bits wide.

A Fourth Example embodiment furthers any one of the first three, wherein the DPI processing circuitry includes: a decompression engine including a set of primary inputs and a set of primary outputs, wherein the set of primary inputs include a character input to provide a byte stream from payloads of the incoming packets to be signature matched, and a state input to provide information based on the alphabet and bitmap compressed DFA for which an instance of signature matching on each byte in the byte stream is either started or continued from, and wherein said set of primary outputs include a signature match detect signal when a signature match is detected and information related to the signature match.

According to a Fifth Example, any of the prior four may be expanded by the bitmap compression process including: (i) an intra-state compression of the alphabet compressed encoded DFA representation using bitmaps, (ii) transition state grouping to group similar bitmaps into leader and corresponding member groups; and (iii) inter-state compression applied to the leader and corresponding member groups using bitmasks.

In a Sixth Example, any of the prior five examples wherein the DPI circuitry operates in two modes, a compression mode to apply alphabet compression and bitmap based compression to the DFA and a fetch mode to signature match bytes of the incoming packets using the alphabet and bitmap based compressed DFA.

According to a Seventh Example, any of the prior six examples may be furthered wherein the DPI circuitry includes address lookup circuit to identify memory addresses relating to the LTT, MTT and ATT memories, a leader transition bitmask fetch circuit and a member transition fetch circuit.

In an Eighth Example embodiment, a hardware accelerator circuit for deep packet inspection signature matching in a communications node using deterministic finite automata (DFA) representing character signatures for matching, the hardware accelerator circuit includes: a processing circuit adapted to accelerate DPI signature matching using compressed DFA by first compressing DFA using an alphabet compression process and a bitmap compression process and then perform signature matching on bytes of incoming packets using the compressed DFA; and a memory coupled to the processing circuit adapted to store representations of the alphabet and bitmap compressed DFA.

A Ninth Example embodiment may further define the Eighth by the memory comprises a static random access memory (SRAM) partitioned into an alphabet transition table (ATT) to store encoded information of alphabet compressed DFA and a leader-state transition table (LTT) and member-state transition table (MTT).

In a Tenth Example embodiment may further define either of the previous two examples wherein the processing circuit includes: a decompression engine including a set of primary inputs and a set of primary outputs, wherein the set of primary inputs include a character input to provide a byte stream from payloads of the incoming packets to be signature matched, and a state input to provide information based on the alphabet and bitmap compressed DFA for which an instance of signature matching on each byte in the byte stream is either started or continued from, and wherein said set of primary outputs include a signature match detect signal when a signature match is detected and information related to the signature match.

According to an Eleventh Example, the three prior examples may further include: data fetch circuitry adapted to apply packet data to the alphabet and bitmap based compressed DFA and identify matching signatures.

In a Twelfth Example, any one of the previous four examples may be expanded by the ATT memory being configured to store 256 encoded DFA entries, each entry being 8-bits wide.

A Thirteenth Example may improve any of the previous five examples wherein the bitmap compression process comprises: (i) an intra-state compression of the alphabet compressed encoded DFA representation using bitmaps, (ii) transition state grouping to group similar bitmaps into leader and corresponding member groups; and (iii) inter-state compression applied to the leader and corresponding member groups using bitmasks

According to a Fourteenth Example any one of the prior six examples may benefit from the processing circuit operating in two modes, a compression mode to apply alphabet compression and bitmap based compression to the DFA and a fetch mode to signature match bytes of the incoming packets using the alphabet and bitmap based compressed DFA.

In a Fifteenth Example, any of the Eighth through Fifteenth examples may be furthered by the processing circuit including an address lookup circuit to identify memory addresses relating to the LTT, MTT and ATT memories, a leader transition bitmask fetch circuit and a member transition fetch circuit.

A Sixteenth Example may further any of the previous eight example embodiments when the processing circuit and the memory are located on a same chip.

A Seventeenth Example embodiment defines a process for signature matching in deep packet inspection (DPI) using a signature set converted into a discrete finite automaton comprising a state machine table representation of signature characters of the signature set, as a plurality of state nodes and state transitions, the method including: simplifying the automaton to compress indistinguishable or unused characters of the signature set and their corresponding state transitions using an alphabet compression process to provide an encoded automaton; applying a bitmap-based compression process on the encoded automaton; and fetching packet data for comparison by the bitmap-based compressed automaton to identify if any signature matches are present in the fetched packet data.

In an Eighteenth Example embodiment, the prior example may further include: storing a representation of the encoded automaton in an alphabet transition table (ATT); and storing bitmap-based compression information of the encoded automaton in a leader-state transition table (LTT) and member-state transition table (MTT).

In a Nineteenth Example either one of the prior two may further include performing intra-state compression of redundant adjacent character transitions of the encoded automaton, segmenting the intra-state compressed automaton into groups having matching bitmaps and designating a leader state and one or more member states for each group; and performing inter-state compression of redundant transitions of member states for each group.

A Twentieth Example may further the Eighteenth Example when the ATT memory is configured to store 256 encoded DFA entries, each entry being 8-bits wide.

Further Example embodiments contemplate a DPI signature matching device include means for performing the steps of processes in any of the Seventeenth through Twentieth Examples.

Context Based Pipelining

As disclosed in and incorporated from the '708 application, FIG. 19 illustrates the hardware-based transition decompression function which is an integral part of the signature matching engine. The hardware acceleration engine which performs the transition decompression function, accepts the sequence of bytes and compares it with the compressed automaton. In one embodiment, each byte in the payload is sequentially input to the state machine. The state transition fetch starts with the root state as the current state. For each incoming payload byte, a state transition lookup is performed for the current state, and byte combination to identify the next state transition. The next state transition is used as the current state for the subsequent payload byte and so on.

In the case of the bitmap-based compression, the state transitions may be compressed and stored in on-chip memories (e.g., memory 154; FIG. 1b). To fetch the compressed state transition for the current state-payload byte combination, it will take multiple clock cycles as shown in the timing diagram 6300 of FIG. 19. In the specific example shown, it would at least take six clock cycles to identify the compressed transition from the memories. Since the state lookup determines the current state corresponding to the subsequent byte, processing bytes of the same packet in every clock cycle is not possible.

To generalize this discussion, say it would take ‘N’ clock cycles to process the byte from the payload. If the operating frequency of the architecture design is assumed to be ‘F’, the signature matching throughput achieved per stream, Tₛₜᵣₑₐₘ is represented by Equation 4 below:

$${T}_{Stream} = \frac{F \times 8}{N} bits per second \qquad ( 4 )$$

As can be seen from Equation 4 and FIG. 19, that the hardware pipeline is not used to its full capacity. The overall throughput reduces by a factor of N, as only a single byte is processed every N cycles.

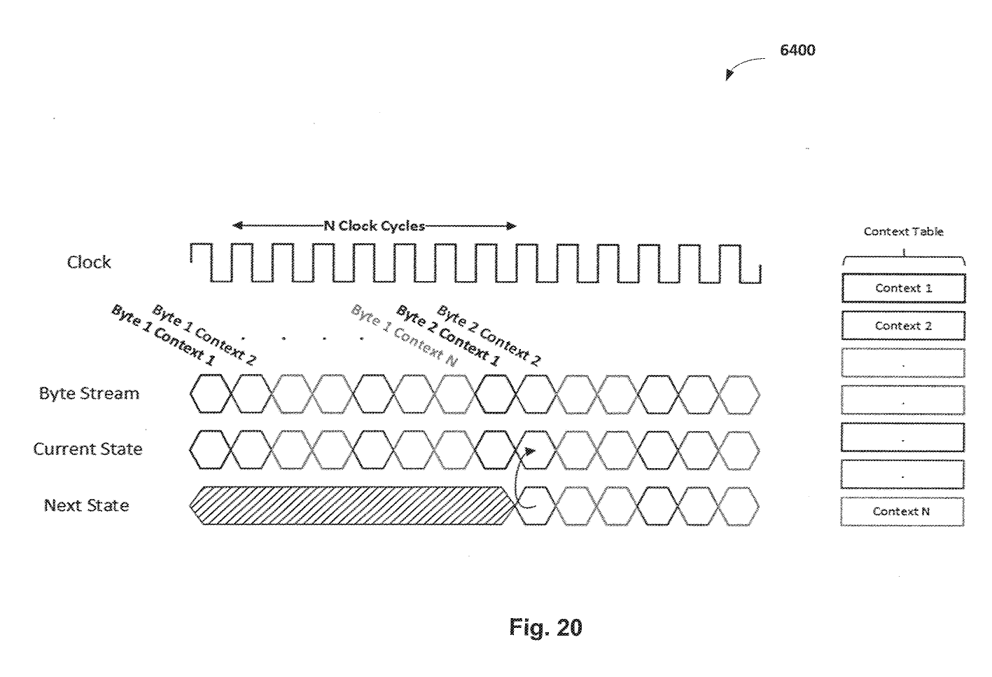

In order to better utilize the hardware pipeline, payload bytes from packets which belong to different network streams may be input to the hardware logic in an interleaved fashion. A network stream is generally defined by a certain specific combination of parameters extracted from the packet headers. In some embodiments, a combination of source, destination IP addresses (OSI L3 header), source, destination port numbers (OSI L4 header) and the OSI layer 4 protocol (TCP/UDP) are used to define a specific stream. This combination of information is typically referred to as the 5-tuple flow. In the example embodiments, each unique stream from which the bytes are sent is referred to as a context and FIG. 20 describes the concept of context. In order to utilize the pipeline efficiently, as shown in the timing diagram 6400, payload bytes from ‘N’ different contexts are sent to the engine in an interleaved fashion over ‘N’ clock cycles. In FIG. 20, to represent this, the byte sequences from different contexts are represented with different shading. For every Nth clock cycle, the byte which is processed by the system belongs to the same context. In order to manage multiple contexts, it is necessary to maintain a context table. The context table will allow monitoring various information pertaining to the signature matching such as the following:

(i) A start and end of the bytes pertaining to a packet or sequence of packets associated with a network stream; (ii) whether there is a single packet or multiple packets which have to be inspected in the stream; and (iii) signature match identification in a context.

With the system processing multiple contexts, the signature matching throughput which can be achieved is shown in Equation 5 below. It should also be noted from the equation below that the signature matching throughput achieved is independent of the value of the number of contexts ‘N’. With an increasing value of ‘N’ the number of entries to be maintained in the context table increases while the throughput achieved remains the same. The signature matching throughput depends solely on the number bytes processed per clock cycle and the operating clock frequency as follows:

$${T}_{Overall} = \frac{F \times 8 \times }{} = ( F \times 8 ) bits per second \qquad ( 5 )$$

Mapping Streams into Contexts

In one embodiment, the signature matching engine is a designed based on the MSBT decompression architecture referenced above, and can be clocked at 1150 MHz (F=1150 MHz, based on synthesis results on the 28 nm semiconductor processing technology). To achieve this frequency, the design is pipelined to perform the transition decompression for a single character in 6 clock cycles (N=6).

Based on Equation 5, to maximize the hardware engine capabilities, there should be six streams in the context table with each supporting data rates of 1533 Mbps (based on Equation 4), to fully utilize the signature matching engine. However, streams with such high data rates are rare in home networking applications. Typically, the home network traffic constitutes many streams (>>N), whose packets are distributed over time. Network processors in home gateways, and similar devices, maintain information about thousands of streams in a stream table as part of their inherent network packet processing. In some embodiments, each stream may be uniquely identified through the network header combination such as the 5-tuple (Source IP Address, Destination IP Address, Source Port Number, Destination Port Number, L4 protocol) flow information. Though the 5-tuple flow information is given as an example to represent a stream, identification of a stream is not restricted to the 5-tuple flow alone and additional or different information from the header can be used to uniquely identify network streams.

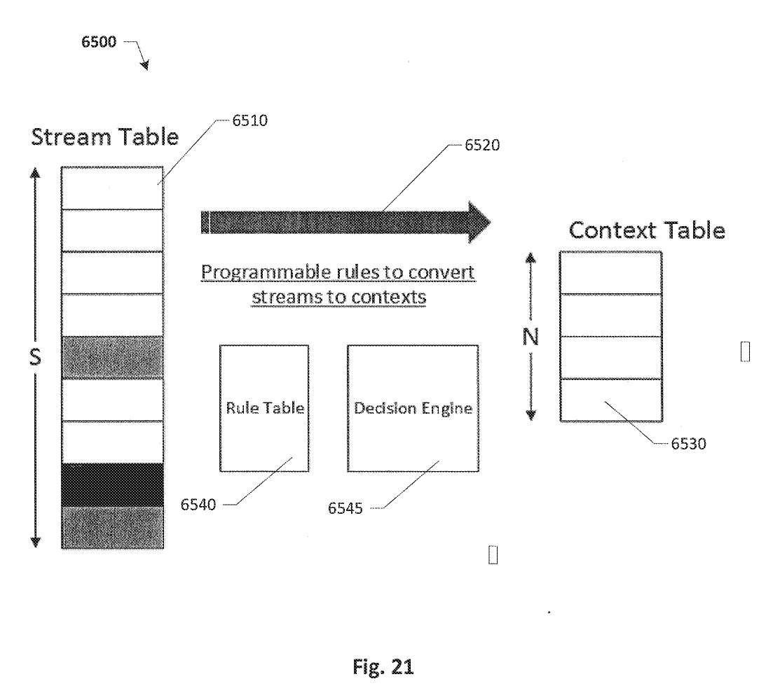

FIG. 21 shows the stream table 6500 with ‘S’ entries on the left which, in certain embodiments, is maintained by the network processor to keep track of the various streams. Each entry in the stream table represents a unique network stream. The context table is shown on the right with ‘N’ entries as shown in FIG. 21, which keeps track of the contexts (N out of S streams) being processed by the bitmap-based transition compression hardware accelerator.

As shown in FIG. 21 the ‘N’ contexts 6530 can be converted 6520 from ‘S’ streams 6510 dynamically, depending on the rules which are programed in the Rule Table 6540. In certain embodiments, each entry in the rule table 6540 can be a programmable rule based on which the entries in the stream table are mapped to the context table. Any streams that are part of the context table can dynamically change over time. For example, at time T, there can be ‘N’ streams mapped to the context table from the stream table, but at a different time T+δ, there can be a different set of ‘N’ streams chosen from the stream table to be part of the context table. A decision engine 6545 may perform mapping of streams to the context table, based on defined parameters in the rule table.

It is not required that streams mapped in the context table be the same at different times. For example, certain streams can have a continuous sequence of packets that satisfy the throughput requirements per stream in the context table and thus their context entries should be maintained in the table. On the other hand, there can be certain streams in which the communication between the host and the client is infrequent. These periodic packet streams may be added to the context table whenever their packets arrive and removed from the context table during voids of packets since retaining these streams in the context table may create a void with respect to the utilization of the signature matching acceleration engine.

Stream table to context table mapping is a base function of the inventive embodiments for devices having a stream table, and the decision engine will serve a key role managing the same. The following are some of the tasks that may be performed by the decision engine 6545: (i) track streams 6520 in the context table 6530 where the signature matching on the sequence of bytes in the packet is about to end; (If there are no subsequent packets in the stream for inspection, the decision engine 545 should preferably remove this stream 6530 from the context table); (ii) identify those critical streams which need to be processed under high priority and include them in the context table 6530; and/or (iii) swapping information between context table 6530 and stream table 6520 to allow smooth functioning of the signature matching engine.

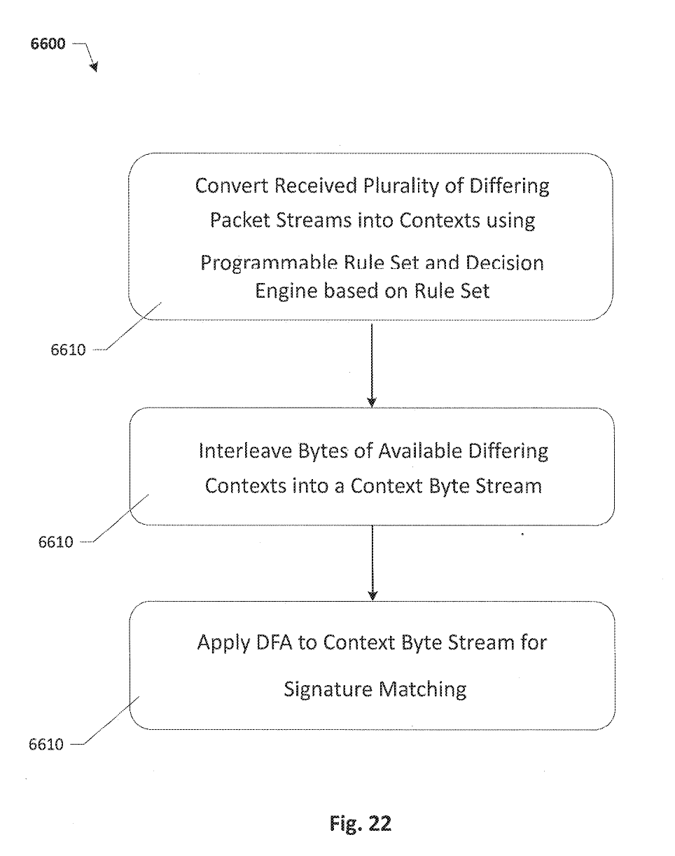

Turning to FIG. 22, a method 6600 of DPI signature matching using content-based byte interleaving may generally include: receiving 6610 a plurality of data packets relating to a plurality of different packet streams each being content-specific; interleaving 6620 bytes of differing content-specific data packets of said received plurality of data packets based on a context table; and comparing 6630 the interleaved packet byte against the compressed DFA.

When the DPI-enabled network device receives a plurality of packets relating to a variety of different packet streams, the streams are converted into contexts using the rule set and decision engine described previously. The contexts may be essentially viewed as a tracking and corresponding handling mechanism to enable packets of the different packet streams to be interleaved byte by byte, each from a different packet stream into a context byte stream for utilizing full potential of hardware capabilities in signature matching, rather than wasting clock cycles focusing on sequential packets of one packet at a time.

In a First Example of context based pipeline embodiments, a device is disclosed for signature matching using deep packet inspection (DPI) to detect content aware application in incoming packets of a communications network using deterministic finate automata (DFA) representing signatures to be matched, the device comprising: a leader-state transition table (LTT) memory; a member-state transition table (MTT) memory; an alphabet transition table (ATT) memory; and DPI processing circuitry coupled to said memories, the DPI processing circuit configured to perform an alphabet compression process on the DFA to simplify indistinguishable characters and corresponding state transitions into an encoded DFA representation to store in the ATT memory, and to perform a bitmap compression process on the encoded DFA representation to further redundant state transitions and store in the LTT and MTT memories.

A Second Example embodiment further defines the First by further including data fetch circuitry coupled to the DPI processing circuit to apply packet data to the alphabet and bitmap compressed DFA and identify matching signatures.

A Third Example embodiment defines a method for signature mating in deep packet inspection (DPI) using a signature set converted into an automaton comprising a state machine table representation of signature characters of the signature set, as a plurality of state nodes and state transitions, the method comprising: simplifying the automaton to compress indistinguishable or unused characters of the signature set and their corresponding state transitions using an alphabet compression process to provide an encoded automaton; applying a bitmap-based compression process on the encoded automaton; and fetching packet data for comparison by the bitmap-based compressed automaton to identify if any signature matches are present in the fetched packet data.

According to a Fourth Example of content based pipelining embodiments, the Third Example also includes: performing intra-state compression of redundant adjacent character transitions of the encoded automaton, segmenting the intra-state compressed automaton into groups having matching bitmaps and designating a leader state and one or more member states for each group; and performing inter-state compression of redundant transitions of member states for each group.

A Fifth Example embodiment discloses a device comprising means to perform the method of prior examples.

A Sixth Example embodiment of context based pipelining includes a hardware accelerator or decompression engine using alphabetic and bitmap-based compression processes as shown and described herein.

Seventh Example embodiment discloses a compressed memory structure to process DPI signature matching as shown and described herein.

Packing Storage Architecture

As disclosed and incorporated from the '256 application, an efficient method and architecture is described for storing bitmap compression data as follows.

Simple Bitmask Storage—Sequential Storage Method & Memory Wastage:

As mentioned above, since the data which is inspected as part of DPI is made up of the ASCII character set, each state in the DFA state table has (256) state transitions corresponding to each character in the ASCII character set. After the intra-state transition compression, the number of state transitions which remain uncompressed in a state are lower than (256) and dynamically varies depending on the character combinations used in the signatures. So, the length of the bitmask varies depending on the signature set and may also vary depending on the organization of the groups after the state grouping step. However, in a theoretical worst case scenario, none of the state transitions in a state may be compressed during the intra-state transition compression. So, the bitmask storage methodology should also be able to support variable bitmask widths which also includes the support for a theoretical maximum of a 256 bit bitmask. Assuming that a 16-bit cumulative transition count (corresponds to an overall total of 2¹⁶ state transitions, when none of the member transitions are compressed) is used for each member state, a 272-bit bitmask entry per state is required to store the MTB along with the cumulative transitions in the worst case scenarios.

The simplest way to store the bitmask is to store the bitmask corresponding to each member state in the memory sequentially. For example, if there are 16-member states, an SRAM memory with 16 address locations with each entry storing 272-bits will be able to accommodate the bitmasks corresponding to all possible member states. This scenario is shown in FIG. 23, where each entry in the table with ‘M’ entries represents the MTB along with the cumulative transitions. The addressing associated with bitmasks is also very simple as each bitmask (associated with a member state) is stored in a single address location.

The biggest problem in the simple approach is that when the bitmask width for the states is lesser than the theoretical maximum of 272-bits, a large portion of memory is wasted as shown in FIG. 24.

In FIG. 24, the bitmask length for various states is shown in the right and their storage in memory is shown in the left. The dotted line represents the portion of the memory which is wasted in each address location when the simplest addressing method is used.

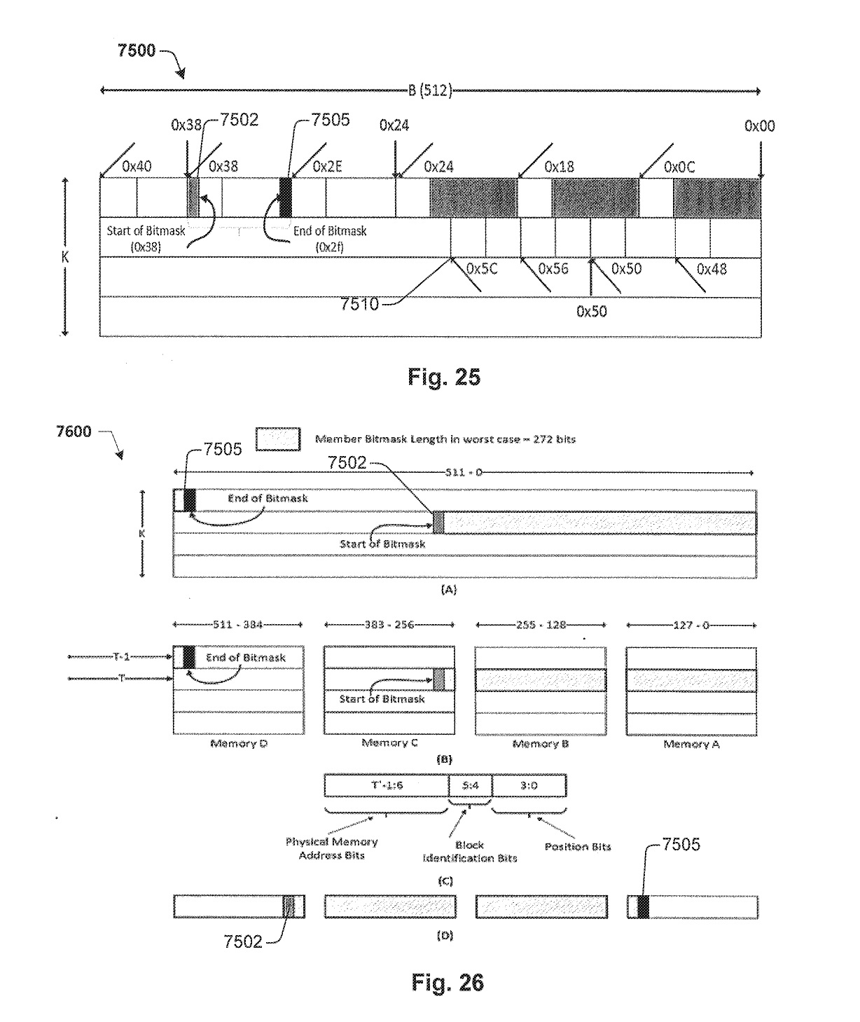

Referring to FIG. 25, in order to solve the problem resulting from the simple sequential storage mechanism, certain embodiments, referred to as a Packed Storage Architecture 7500, disclose a process where bitmasks are stored in a much less wasteful and more efficient manner. The example of FIG. 25 uses the same bitmasks as illustrated in FIG. 24.

In these embodiments, bitmasks are stored in a contiguous fashion in the physical memory as compared to what is shown in FIG. 24. The width of the physical memory is also wider in comparison to the one shown in the simple storage architecture. FIG. 25 shows a piece of memory with B (512 assumed for this example) bits per address line with K addresses in the memory. The key difference from the simpler architecture is that multiple bitmasks are stored in a single address line. So once the bitmask corresponding to a state is stored in the memory, it is immediately followed by its successor without wasting any space. In order to uniquely address each and every MTB, byte level addressing is used in the memory. In order to support byte level addressing, those bitmasks whose length is below a byte level boundary is padded with additional 0's in the most significant bit positions. For example, after compression, if a 46-bit MTB is generated, two bits are additionally padded to make it a 48-bit MTB. In the packed storage architecture embodiments here, the MTB and the cumulative transition count are stored continuously in the memory. The start address location of every bitmask is shown by angled arrows while the starting address of the first bitmask in each and every group is demarcated using a vertical arrows.

Table 5 below details the address calculation mechanism in which the addresses for each and every bitmask can be calculated. In order to calculate the start address 7502 of each bitmask, the base location from which the bitmask address is calculated (shown in black arrow in FIG. 25) and the length of the bitmask is stored in another memory called the “Address Mapping Table”. Since the bitmap for all the states in a group is the same, the length of the bitmask for the member states in a group is also the same and is stored only once for a group.

The compressed state transition that is stored in the memory is encoded as a combination of leaderID and the memberID as shown in FIG. 2(f). The leaderID identifies the group to which a state belongs to and the memberID identifies if a state is a leader or a member state.

The start address location of the bitmask corresponding to a member state is calculated as the product of the memberID and the bitmask length which is further added with the base address.

TABLE 4
Address locations of MTBs of various member states

| | | Base | | Calculated |
|---|---|---|---|---|
| Group ID | Member ID | Address | Length | Address |
| 0x1 | 0x1 | 0x01 | 0xC | 0x0C |
| | 0x2 | | | 0x10 |
| | 0x3 | | | 0x24 |
| 0x2 | 0x1 | [symbol] | 0xA | 0x28 |
| | 0x2 | | | 0x38 |
| 0x3 | 0x1 | [symbol] | [symbol] | 0x40 |
| | 0x2 | | | [symbol] |
| | 0x3 | | | [symbol] |
| 0x4 | 0x2 | [symbol] | [symbol] | [symbol] |

[symbol]

indicates data missing or illegible when filed

For example, the bitmask address corresponding to the member state ‘2’ (i.e., MemberID: 0x2) in group ‘1’ (i.e., LeaderID: 0x1) is calculated as: Bitmask Start Address=(0x2*0xA)+0x24=0x38.

Once this address 7502 is calculated and the bitmask length is known, the actual MTB and the cumulative transition count can be fetched between address locations 0x38 and 0x2F as shown in FIG. 25.

FIG. 26 illustrates certain inventive embodiments where a bitmask is stored across multiple physical addresses. As shown in FIG. 26(A), a worst case scenario is when the longest bitmask, i.e., one that is 272-bits wide, and is spread across multiple physical memory locations of a 512-bit memory, yet still has to be fetched in a single clock cycle. In order to support this potential scenario, the physical memory may be vertically split. As shown in FIG. 26(B) in order to fetch a 272-bit bitmask from memory in a single clock cycle, the 512-bit memory is broken down into four pieces A, B, C and D, each having a width of 128-bits. The individual physical memory location from the split memories where the bitmask data is stored, may vary depending on the start address of the bitmask. The physical address location corresponding to the bitmask start address 7502 in this example, is assumed to be at location ‘T’. As shown in FIG. 26(B), since the bitmask start address resides in memory C, the 128-bit data is fetched from address location T in memories C, B and A while the data is fetched from memory physical memory location T−1 in memory segment D. When the bitmask data is fetched from the split memory, the data may be reconstructed as shown in FIG. 26(D).

FIG. 26(C) shows the T′ bit start address of the bitmask which was calculated before with the bitmask length and the memberID. The calculated start address can be split into three portions. The lower most 4-bits called the “Position Bits” identifies the position of the bitmask start address within the 128-bit memory. Bits ‘5’ and ‘4’, called the “Block Identification Bits”, identify to which memory vertical (i.e., memory A/B/C/D) the start address belongs to. The third portion is defined as the “Physical Memory Address Bits” which is directly used to identify the physical memory address for the four memories. For example, if T′ is set to 12-bits, the physical memory address gets 6-bits (K=64), which implies that each memory vertical (A/B/C/D) has (64) address locations with 128-bits of information stored in them.

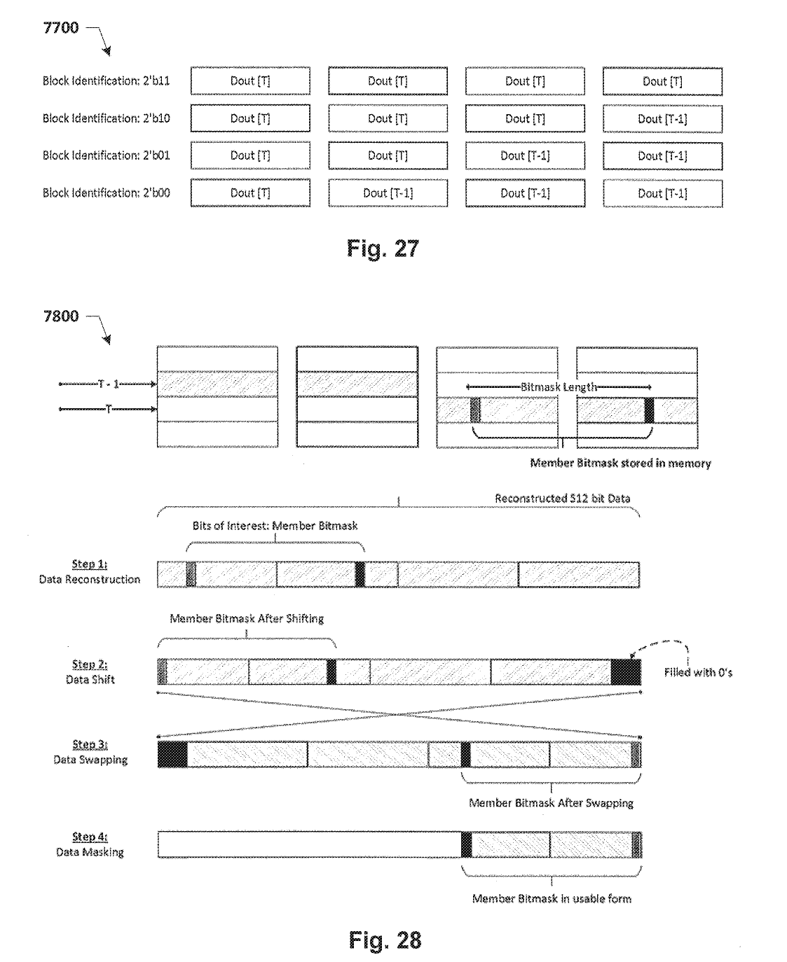

FIG. 26(D) showed how the 512-bit data is reconstructed if the start address T belongs to the physical memory block C. FIG. 27 shows a generic way of how the 512-bit data is reconstructed depending on the block identification bits in the start address. For example if the block identification bits are 2′b00, the bitmask starts in the memory block A (physical memory address T) and extends to the previous physical addresses (T−1) in memory block D, C and B respectively. So the 512-bit data is constructed with the 128-bits of data from address T in memory A, followed by 128-bits of data from address T−1 in memory D, C and B respectively. The reconstructed data from the physical memory address T is shown using “Dout[T]” while the ones from physical address T−1 is shown with a Dout[T−1] in FIG. 27.

FIG. 27 shows how the bitmask data is fetched from the memory in a single clock cycle, even in an extreme case scenario of fetching 272-bits of data from the memory. A next process is to extract the necessary bitmask from the reconstructed data from memory for further processing.

FIG. 28 details the steps in the data extraction, after fetching the data from the memory. In some examples, there may be four general steps in a method 7800 of storing and retrieving the data from the memory arranged by the packed storage architecture embodiments described herein.

Data Reconstruction: This is the first step on how the 512-bit data with the bitmask is constructed after being fetched from the memory discussed above.

Data Shift: In this step, the data which is fetched from the memory is left shift by certain positions. This is to bring the intended MTB and the cumulative transition count to the most significant bit position. The number of bytes by which the data is shifted can be identified by the position bits in the calculated bitmask address. For example, if the bitmask address is in byte position ‘0’, the data is shifted by 15-byte positions. In general, if the byte level position of the bitmask is ‘P’, the number byte level shifts corresponds to ‘15-P’.

Data Swap: In this step, the data is swapped bit by bit, between the most significant and least significant bit positions. For example, the data in bit position (511) is swapped with bit position 0. Similarly, data in bit position (510) is swapped with data in bit position (1) and this process continues until all the data the 512-bit data is swapped. In order to support this swapping step, the data may be swapped and stored in memory by an MSBT compiler. This step is performed to bring the data to the usable form.

Data Masking: This is the last and final step to extract the MTB and the cumulative transition count. Out of the 512-bit data that is fetched from the memory, only a certain portion of the data contains the MTB and the cumulative transition count. This is defined by the bitmask length and the rest of the data is masked out. So a decoder is used to generate a mask which can extract the relevant data out of the 512-bit data from the memory.

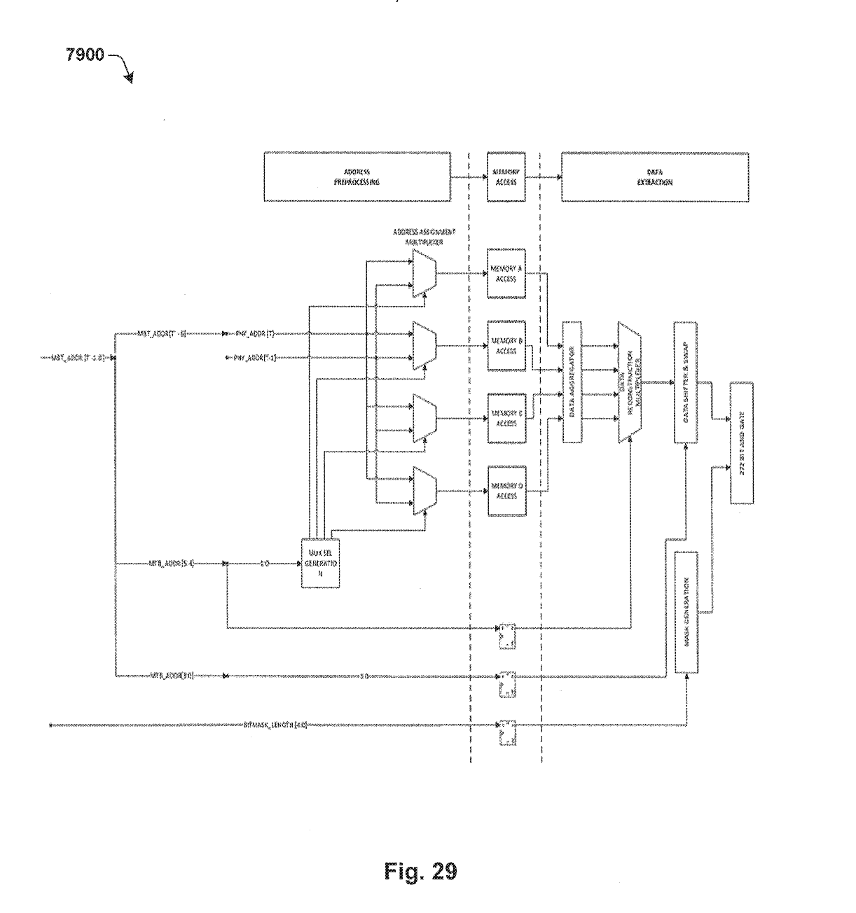

FIG. 29 gives a description of hardware blocks to fetch and extract the MTB and the cumulative transition information from the memory. The logic blocks associated with the MTB access can be separated into the ‘Address pre-processing’ and the ‘Data Extraction’ blocks. The address pre-processing block multiplexes the physical memory address between T and T−1 as explained previously. The address location T−1 can be generated in parallel to T or can be calculated after the MBT address calculation which generates T by performing a subtraction operation. The select signal for the multiplexer is generated based on the block identification bits extracted from the bitmask start address.

The post-processing block in certain embodiments, is made up of the data aggregator, the data reconstruction multiplexer, the data shifter and the mask generation encoder. The data aggregator block receives the data from the memory and prepares the combinations of the reconstructed data according to the block identification bit combination as shown in FIG. 27. One of the reconstructed 512-bits is chosen by the multiplexer and the registered block identification bits drive the select signal in the multiplexer. The data shifter block is a multiplexer whose select signal is fed by the registered “position bits” in the calculated address. The mask generation block is made up of a decoder which sets a certain range of bits to ‘1 or 0’ depending on the registered bitmask length. The extracted data is finally masked by performing a bitwise “AND” operation with the encoded bitmask length signal.

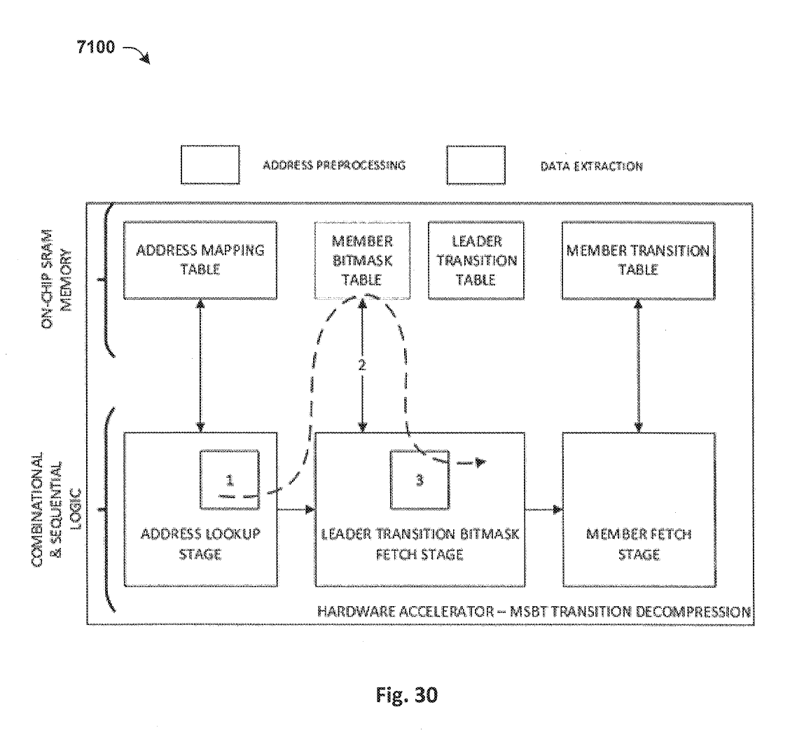

FIG. 30 shows the block level architecture of the MSBT based hardware accelerator which can perform the transition decompression in a dedicated hardware. This hardware engine was designed in Verilog and synthesized on a 28 nm technology library. The design has been pipelined to achieve clock frequency of about 1.150 MHz, which corresponds to ˜9.5 Gbps of signature matching.

The various embodiments of “Packed Storage Architecture” may be used in this hardware accelerator to store the bitmasks efficiently as well as fetch them in a single clock cycle to achieve transition decompression at multi gigabit rates. The hardware architecture can be split into two blocks i.e. the logic and the memory blocks. The memories store the compressed transitions along with the control information such as bitmaps, bitmask, base addresses etc. which help to identify the compressed state transition. The logic block consists of all the necessary logic circuitry that calculates the addresses to fetch the necessary information from the memory blocks. The logic and the memory blocks are split into three functional stages. In a first stage, the base addresses, the bitmap and the bitmask length are fetched from the “Address Mapping Table” (AMT) while the corresponding memory addresses for all the next (2) stage is performed in the “Address Lookup Stage.” The “Address pre-processing” circuitry discussed in the previous section belongs to the address lookup stage in which the start address for the bitmask is calculated. The next stage is called (3) the “Leader Transition Bitmask Fetch Stage” in which the bitmask is extracted from the data that is fetched from the memory. The bitmask is stored in the “Member Bitmask Table” using embodiments for packed storage architecture discussed herein. The “Data Extraction” hardware circuitry is part of the second stage. Depending on the information extracted and processed from the member bitmasks, the compressed transition is either fetched from the leader or the member transition tables (note, even though the drawing references is as its own stage, the 1-2-3 numerals in the drawing reference the three overall stages.

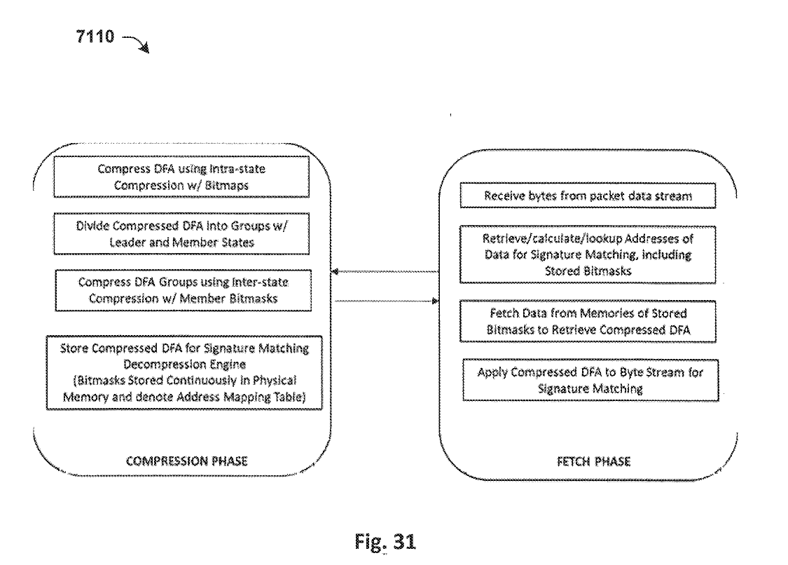

Turning to FIG. 31, a method of DPI signature matching using the package storage architecture of the inventive embodiments, may generally include two phases of operation, as mentioned previously: (1) a compression phase where the DFA for each signature may be compressed using the MSBT process described previously and storing the compressed DFA as bitmasks reducing redundant transitions; and (2) a fetch phase, where the compressed DFA is retrived from memory and applied to a byte stream from a plurality of data packets of incoming traffic packet streams.

Examples of the PSA inventive embodiments are as follows:

### Example 1

A method of communication using a deterministic finite automata (DFA) representation of signatures to be matched, as characters and state transitions to a next character of the signature to be matched, for line rate signature matching in deep packet inspection (DPI), the method comprising: compressing the DFA using an intra-state bitmap compression step comprising reducing identical state transitions adjacent to each other in each state through one or more bitmaps; arranging the intra-state compressed DFA into clusters having similarly sized transition groups, each group being assigned a leader state and one or more member states; further compressing the DFA using an inter-state bitmask compression step comprising reducing redundant transitions between member states of each group through one or more bitmasks; and storing said bitmasks contiguously in a physical memory, one after another, using byte level addressing in said physical memory, such that multiple bitmasks may possibly be stored in a single address line and one bitmask may possibly be stored over two address lines in said physical memory.

Example Two further defines Example One wherein an address of said bitmasks being stored are written to an address mapping table encoded as a combination of a leaderID and a memberID associated with a cluster of grouped leader and member state transitions.

A Third Example further defines either the first examples by applying said further compressed DFA to a byte stream of incoming network traffic to determine whether a signature is matched by looking up an address of a desired bitmask in the address memory table, fetching said desired bitmap from said physical memory based on the addressed looked up, and applying the bitmask in signature matching processing.

A Fourth Example may add to any of the first three wherein at least part of said physical memory is partitioned into four pieces each having a width of 128 bits and each piece being split vertically such that a 272-bit maximum size bitmask may be retrieved from the physical memory in a single clock cycle.

In a Fifth Example, a device is disclosed comprising means for performing the steps of any of the prior Example embodiments.

A Sixth Example embodiment may define an apparatus for use in DPI signature matching using a deterministic finite automata, the apparatus comprising: a decompression engine including a DPI hardware accelerator configured to perform intrastate compression using bitmaps and interstate compression using bitmasks on the DFA; a memory to store and access: (1) an address mapping table and (2) the bitmaps and bitmasks used by the DPI hardware accelerator for compression of the DFA and signature matching processing; wherein the bitmaps are stored in said memory contiguously, one after another, using byte level addressing in said physical memory, such that multiple bitmasks may possibly be stored in a single address line and one bitmask may possibly be stored over two address lines in said physical memory.

A Seventh Example may include any feature of the previous examples wherein an address of said bitmasks being stored are written to an address mapping table encoded as a combination of a leaderID and a memberID associated with a cluster of grouped leader and member state transitions.

An Eighth Example may define a system for deep packet inspection (DPI) signature matching using a bitmap-based compressed deterministic finite automata (DFA), the system comprising: at least one network interface configured to receive packet data streams; a DPI processing circuit configured to perform signature matching by applying the compressed DFA to a byte stream pertaining to packets being inspected of the received packet data streams; and a memory configured to store information accessible by the DPI processing circuit regarding the compressed DFA, including one or more bitmasks to perform said signature matching; wherein said bitmasks are stored contiguously in said memory, one after another, using byte level addressing in said physical memory, such that multiple bitmasks may possibly be stored in a single address line and one bitmask may possibly be stored over two address lines in said physical memory.

As another Example embodiment the context based pipeline embodiments immediately above, may combine any of the features of any other example embodiments disclosed herein. For example, at the DPI processing circuit and the memory comprise a hardware accelerator circuit in a signature matching decompression engine, perform alphabet compression and packed storage architecture embodiments.

Compression Technique—Independent Hardware Accelerator:

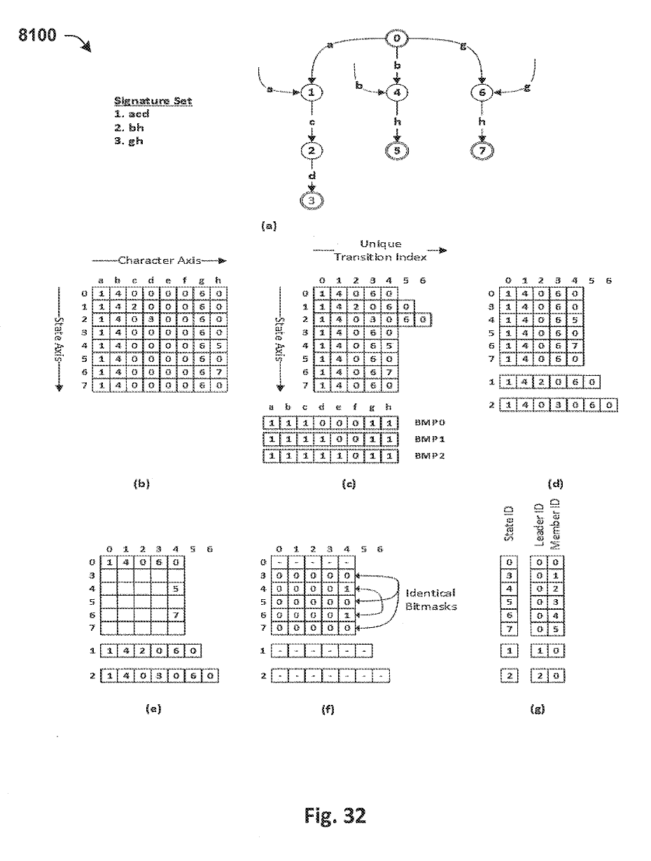

Referring to FIG. 32-36 as disclosed and incorporated from the '707 application, an improved compression method and architecture embodiments will now be described.

A refresher regarding the bit-map compression techniques discussed previously in FIG. 2 will be given in reference to FIG. 32(a)-(e).

Member State Bitmask Technique (MSBT)

FIG. 32 shows a process 8100 of transition compression performed on the specific combination of signatures ‘acd’, ‘bh’ and ‘gh’. The characters in the signatures belong to the character set Σ={a,b,c,d,e,f,g,h}. It should be noted that the signature set has multiple occurrences of character ‘h’ among the 3 signatures. A character occurring in different signatures is very common in real life signature sets. But the location of these characters within the signature sets could vary and doesn't affect any of the details in this invention disclosure.

FIG. 32 (a) shows the conversion of the signatures into the DFA. The incoming arrows shown in blue color into the states 1, 4 and 6 are those state transitions which converge from all the states excluding the root state on the characters displayed on the state transitions. The state table corresponding to the DFA is shown in FIG. 32 (b). FIG. 32 (c-g) shows the various steps involved in the MSBT, which is a 3-step transition compression method to compress the redundant transitions in the DFA. The MSBT is a 3 step method which includes the intra-state transition compression, followed by the state grouping step and the inter-state transition compression.

In FIG. 32(c) those identical state transitions which are adjacent to each other within each state through bitmaps are compressed. The characters at which the transitions are compressed is marked with a ‘0’ in the bitmap (e.g. in BMP0), while those at which it is not compressed is marked with ‘1’. After intra-state compression, the states are split across three different bitmaps which are represented through shades in FIG. 32(c). The state grouping is the second step where the states are clustered into groups using the divide and conquer state grouping algorithm. FIG. 32(d) shows the DFA after the state grouping step. The last and the final step is the inter-state compression, where the redundant transitions between various states in a group are compressed through the bitmasks (a.k.a. member transition bitmask (MTB)).

For example, as seen in FIG. 32(e), the state transitions corresponding to index 4 in states 3, 5 and 7 are compressed as they are the same as the transition in state 0. The state transition which is compressed during the inter-state compression is identified by a ‘0’ stored in the bitmask as seen in FIG. 32(f), while the ones which are not compressed are identified by a ‘1’ in the bitmask (as seen in the MTB for state 4 at index 4 in FIG. 1(f)). FIG. 32(g) shows the encoding of the DFA states after the MSBT. The states are encoded into leaderID and the memberID. The leaderID represents the group to which a state belongs to while the memberID represents the individual representation of a DFA state within the group. After MSBT compression, the compressed DFA is split into compressed transitions and control data to include the bitmaps and the bitmasks

Motivation: Based on the analysis of the state transitions generated in a DFA, they can be classified into four categories as shown below:

Root State Diverters: These are the transitions corresponding to those characters in the DFA which are not represented in the signature set. These transitions always lead to the root state (stateID=0) and are uniform across all the states in a DFA. Eg. State transitions corresponding to characters ‘e’ and ‘f’ seen in FIG. 32(b) belongs to this category.

Partial Matches: These are the state transitions which lead to a partial or a successful signature match. Generally the state transitions corresponding to a single/multiple characters across various states which result in a partial match are different from the state transitions corresponding to the character(s) in other states. For example, the state transition corresponding to character ‘h’ in states ‘4’ and ‘6’ lead to a signature match and the state transitions corresponding to ‘h’ is different, especially for these two states in comparison to other states.

Failure Matches: After successfully matching a signature partially/fully, the state transitions corresponding to the characters which do not continue with the partial (or even full) signature match, are directed to the root state. This is the category which is exactly to opposite to that of the partial matches. For example, the state transition corresponding to the character ‘h’ in state two belongs to this category.

Initiators: The state transitions associated with the characters which are the first character in each of the signatures, always direct to a certain unique state across all the states in the DFA. For example, the state transitions corresponding to characters ‘a’, ‘b’ and ‘g’ lead to states ‘1’, ‘4’ and ‘6’ across all the states.

The composition and the sequence of the characters in the signatures determine the state transitions in the DFA. The state transitions in the DFA directly affects the patterns which form in the MTBs after the inter-state compression. A discussed earlier, majority of the state transitions in a DFA belongs to the state transition categories apart from the partial matches and are redundant. The state transitions which belong to the initiator and the root state diverter are very linear across states and the bitmask bit resulting from these transitions are always ‘0’. On the other hand, the state transitions from the partial matches are the ones which vary across different member states potentially varying from each other to generate a ‘1’ in the MTB after inter-state compression. With same characters occurring across multiple signatures, the partial matches will differ across various states and generate identical MTB patterns after the inter-state compression. This scenario can be seen in the case of states ‘4’ and ‘6’ which differ from the root state corresponding to unique transition index 4 (character ‘h’), where the state transition is a partial match. Leveraging on this observation of identical MTBs generated among the member states, it is confirmed that a certain patterns will be repeated in the MTB and need not be stored multiple times. So these redundant MTB patterns can be compressed to reduce the memory usage to store the control data in a compressed DFA.

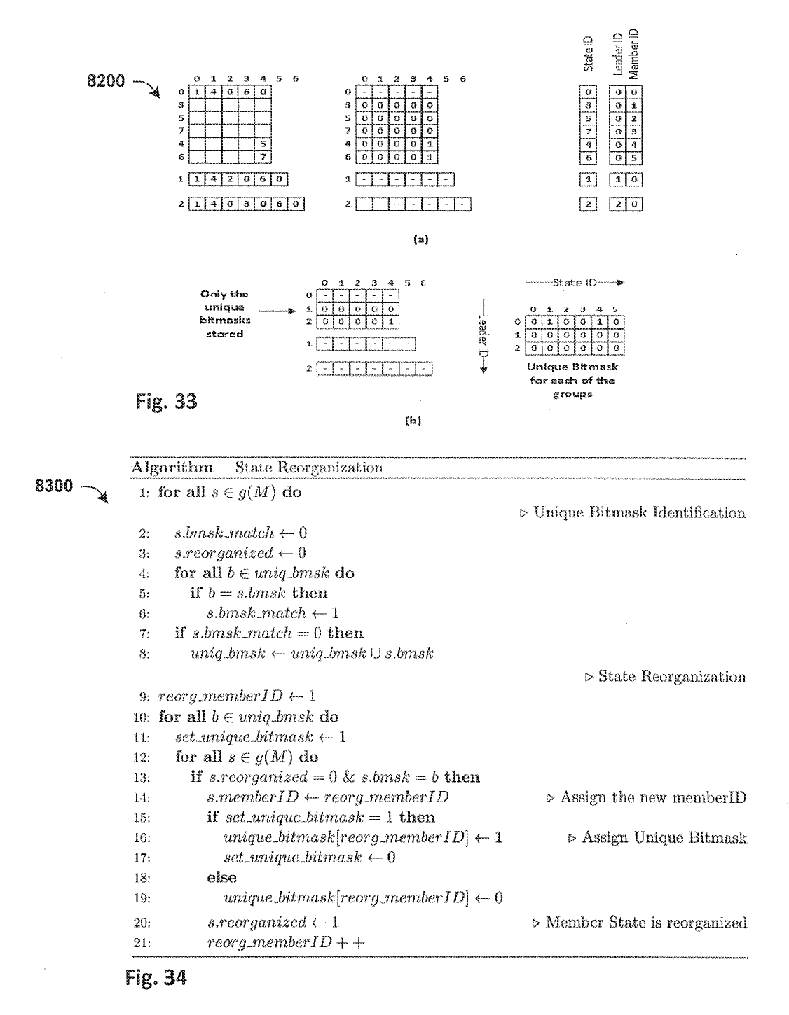

As seen in FIG. 33(f), the MTBs which are identical, do not always occur next to each other as they are spread across the whole of the DFA. So the member states have to be reorganized in such a way that the MTBs which are identical always occur next to each other.

FIG. 33 shows a process for bitmask compression where FIG. 33(a) shows the reorganized member states. The states ‘3’, ‘5’ and ‘7’ which had identical MTBs are organized first followed by states ‘4’ and ‘6’ which also have identical MTBs but different from the previous one. The reorganization of the states also requires the memberID's corresponding to the states to be modified. For example, the original memberID corresponding to state ‘4’ is ‘2’. But, after reorganizing the states to compress the MTBs, the memberID corresponding to ‘4’ is set to ‘4’.

After reorganizing the states, the bitmask compression is performed to remove the redundant MTBs among the member states. A unique_bitmask identifies if the MTB of the member state within a group is compressed during the bitmask compression. The unique_bitmask is as wide as the number of member states in a group. If there is a maximum of B states in a group, the unique_bitmask consists of B bits to identify if a member state's bitmask is compressed or not. The bit in the position corresponding to the memberID is set to 1, if the MTB corresponding to the member state is not compressed, while it is set 0 if it is compressed.

FIG. 33(b) shows the bitmask compression performed in the example embodiment. The MTB's corresponding to states ‘5’ and ‘7’ are compressed as they are identical to the MTB of state ‘3’. Similarly the MTB of state ‘6’ is compressed as it is identical to that of state ‘4’. Since there are a maximum of 6 states in the first group, there is a 6-bit unique_bitmask to identify the states whose MTBs are compressed. The bit position corresponding to indices ‘1’ and ‘4’ are set to 1 as the MTBs corresponding to their states are not compressed while the others are set to 0. The unique_bitmask bit corresponding to the leader state is always set to 0 as it doesn't have an MTB. Even though the other groups do not have any member states, the unique_bitmask is created for them to maintain the uniformity in the unique_bitmask construction.

FIG. 34 shows the pseudocode process 8300 for the state reorganization algorithm used for bitmask compression according to various embodiments. The algorithm is split into two parts. The first part identifies and segregates only those MTBs which are repeated among the member states. This is done by examining the MTB corresponding to each of the member state and organizing those unique MTBs into the ‘unique bitmask’ (uniq_bmsk) set. After the first step, the unique bitmask set only consists of those MTBs which are non-identical among the MTBs which must be stored in the memory. As a next step, each of the bitmask in the ‘unique bitmask’ set is compared against the bitmasks of the member states. The second step is called the state reorganization step where the memberID's are sequentially reallocated in such a way that the states which have identical bitmasks are organized next to each other. The unique bitmask bit for each of the member states is also created in this step to identify the member states whose bitmasks are compressed as discussed before.

Structured Methodology to Compress an Automaton:

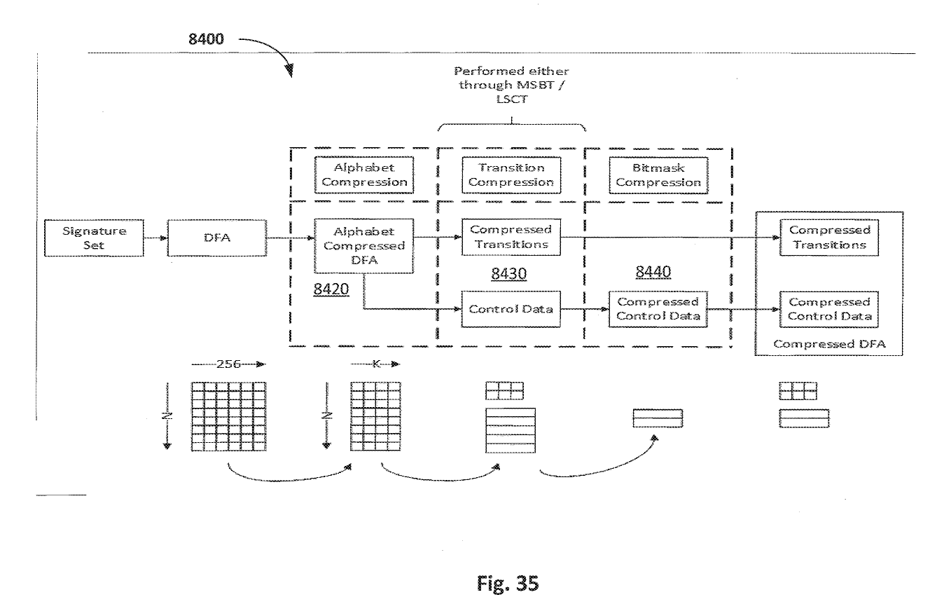

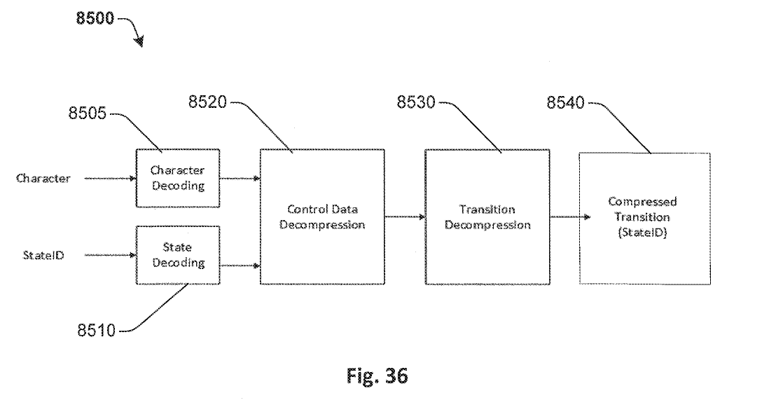

Referring to FIG. 35, a process 8400 is shown for compressing an automaton or a DFA through multiple levels to its most efficient compressed form. According to certain embodiments, progressive levels of compression may be performed on the DFA from its initial uncompressed form to an efficient compressed format.

There are various hardware oriented methods such as MSBT previously discussed and others which can compress the redundant transitions in an automaton. The biggest advantage of using these algorithms to perform transition compression is that the transition decompression which is a very important part in signature matching can be performed in a dedicated hardware accelerator. The MSBT and other compression techniques, generally referred to as transition compression methods, generate the second level mask indicators (bitmasks) to achieve high degree of transition compression. After the compression, the compressed transitions along with the control data which helps to identify the compressed transition are stored in on-chip SRAM memories. The various steps involved in the structured compression methodology are explained further.

In one embodiment, the first step is to convert a signature set into a deterministic finite automaton (DFA). The DFA is a 2-dimentional array and in certain embodiments, it consists of state transitions for the ‘256’ characters of the extended ASCII character set, although basic ASCII, Unicode or other character sets may be utilized as desired, where each character of a given set corresponds to one DFA state, i.e., ‘256’ states in this example embodiment. The American Standard Code for Information Interchange (ASCII) is the most common format for text files in computers and on the Internet. The original, or basic ASCII file defines ‘128’ alphabetic, numeric, or special characters, each as a 7-bit binary number (a string of seven 0s or 1s). More prevalent now, and used in the example embodiments described, is the extended ASCII set, which uses 8-bit strings to define ‘256’ characters. “ASCII,” as referenced herein, may mean either, except where specific numerologies clearly require a certain number of characters. Essentially, each signature is mapped in from the 256-ASCII available character set, as a state and transition to a next state to form the signature matching automaton.

The second step is to perform alphabet compression 8420 in which the alphabets in the ASCII character table are compressed. Due to the organization of the characters in the signature sets used for DPI, certain characters in the ASCII character set are indistinguishable and therefore, can be compressed. The state transitions corresponding to the characters which are compressed during alphabet compression are also compressed in this process.

For example, before alphabet compression 8420 the original character set consists of 256-characters and after alphabet compression, it is reduced to an encoded character set consisting of ‘k’ (k<256) unique distinguishable characters. The value of k varies depending on the combination of characters which are part of the signature set. After alphabet compression, the alphabet compressed DFA which is generated is a 2-dimensional state table which consists of ‘k’ state transitions per state instead of the original 256-state transitions per state. In the current implementations, the number of states in the DFA remains the same after alphabet compression. An Alphabet Transition Table (ATT) stores the encoded characters corresponding to each of the character in the ASCII character set.

The third step is to compress 8430 the redundant state transitions in the alphabet compressed DFA. The redundant state transitions are compressed either using the MSBT or other bitmap-related transition compression methods 8430. After the transition compression is performed, the compressed DFA is split into two portions, the compressed state transitions and the control data. The compressed state transitions represents about 1-2% of the original state transitions in the DFA. The control data represents the control information which is essential to identify the compressed transition corresponding to the incoming state-character combination. The control data is composed of information such as bitmaps, bitmasks (member transition bitmask alone in the case of MSBT) and certain addressing information.

In some embodiments, bitmap-based transition compression 8430 can be performed without the alphabet compression though the resulting number of transitions compressed are slightly higher when alphabet compression is combined together with transition compression.

The last and the final step in the DFA compression is the bitmask compression 8440 described in these embodiments. The bitmask compression 8440 focuses on compressing the redundant MTBs generated as part of the transition compression. The bitmask compression results in a reduced memory usage in storing the compressed MTBs with a small cost paid to store the additional control information to identify if a member state's MTB is compressed or not.

After implementing the proposed structured compression methodology, the original DFA which is a two dimensional state table is converted into a compressed DFA. The compressed DFA is composed of the compressed state transitions and the compressed control data. The compressed state transitions are the same as what was generated after the transition compression. The compressed control data consists of the base addresses, bitmaps, compressed MTBs and the unique bitmask.

FIG. 36 shows an overview of processing 8500 that may be performed as part of the transition decompression when the DFA is compressed using the above mentioned methodology of FIG. 35. The basic inputs provided to start the decompression is the character and the stateID combination for which the corresponding state transition has to be identified amongst the compressed state transitions.

The first step performed as part of the transition decompression is the character decoding 8505 and the state decoding 8510. The character decoding 8505 step identifies the encoded character representation corresponding to the incoming character which is further used for transition decompression. The state decoding 8510 splits the incoming state into its leader and memberID based on which the further processing steps can be decided out. The character and the state decoding are performed either in parallel or in sequential manner depending on whether the decompression is performed in a dedicated hardware or a software. If the decompression is performed in a hardware based implementation, both the decoding steps can be done in parallel. If the decompression is performed in a software, then they have to be done sequentially. There is no hard requirement on the sequence of the processing between the character and the state decoding.

In Example embodiments without the alphabet compression is removed from the above structured compression method, the character encoding step is removed.

The second step is the control data decompression 8520. The control data decompression is only performed, if the incoming state is a member state. If the incoming state is a member state, then it is identified if the MTB corresponding to it is compressed or not. Depending on whether the control data is compressed, the MTB corresponding to the state is identified from the memories which is further used for transition decompression.

The third and the final step is the transition decompression 8530, where the location of the compressed transition is identified based on the control data that is fetched from the control memories. The compressed state transition 8540 corresponding to the character-stateID is also a stateID which is used as the input for the subsequent character in the payload bytes.

The structured method discussed above structurally combines various compression techniques through which an automaton is compressed to generate an efficient memory footprint.

### Example Embodiments

In a First Example embodiment, a method of DPI signature matching includes: converting a signature set into a signature matching deterministic finite automaton (DFA) comprising a 2-dimensional array of state transitions of a signature set corresponding to states in an ASCII character set having 256 characters; optionally, applying alphabet compression to generate an encoded character set DFA as a 2 dimensional state table consisting of ‘k’ transitions per state, wherein a value of ‘k’ varies is based on a combination of characters of the signature set, and wherein ‘k’<256, and storing the encoded character set in an alphabet transition table (ATT); applying bitmap compression to compress redundant adjacent state transitions in the alphabet compressed DFA and to compress control data comprising at least one of bitmaps, bitmasks and addressing information; arranging the bitmap compressed DFA into clusters having similarly sized transition groups, each group being assigned a leader state and one or more member states; applying bitmask compression further compressing the DFA by reducing redundant transitions between member states of each group through member state bitmasks; and applying bitmask compression to compress identical member state bitmasks.

In a Second Example embodiment, a method of DPI signature matching includes compressing the DFA using an intra-state bitmap compression step comprising reducing identical state transitions adjacent to each other in each state through one or more bitmaps; arranging the intra-state compressed DFA into clusters having similarly sized transition groups, each group being assigned a leader state and one or more member states; further compressing the DFA using an inter-state bitmask compression by reducing redundant transitions between member states of each group through one or more bitmasks; compressing identical member state bitmasks resulting from the inter-state bitmask compression step.

In a Third Example embodiment, a method of decompressing information in a DPI signature matching engine, the method includes: receiving an incoming character; determining if the incoming character is alphabet compressed, and if so, decoding an encoded character representation corresponding to the incoming character used for transition decompression by splitting an incoming state into its leader and memberID; and determining if the incoming character is associated as a member state, and if so, determining whether the incoming character is compressed or not, and if so, the fetching an associated member transition bitmask corresponding to the member state from a bitmask memory based on a character-stateID is also a stateID which is used as the input for the subsequent character in the payload bytes.

In a Fourth Example embodiment, the Second Examples may further include compressing redundant control data information relating to bitmaps, bit masks and related addressing.

In a Fifth Example embodiment, a device is disclosed for deep packet inspection comprising means for performing the steps of any of the prior Examples.

In a Sixth Example embodiment, an apparatus is disclosed for use in DPI signature matching using a deterministic finite automata, the apparatus comprising: a decompression engine including a DPI hardware accelerator configured to perform intrastate compression using bitmaps and interstate compression using bitmasks on the DFA and to compress control data including redundant bitmaps bitmasks addressing information related to their storage; a memory to store and access: (1) an address mapping table and (2) the bitmaps and bitmasks used by the DPI hardware accelerator for compression of the DFA and signature matching processing; and (3) to store the control data.

In a Seventh Example embodiment, any of the example embodiments of context based pipelining, may use a hardware accelerator or decompression engine with alphabetic and bitmap-based compression processes as shown and described herein or any other example embodiment combinations are specifically contemplated.

An Eighth Example embodiment discloses a compressed memory structure to process DPI signature matching as shown and described herein

Deep Packet Inspection Accelerator System Architecture

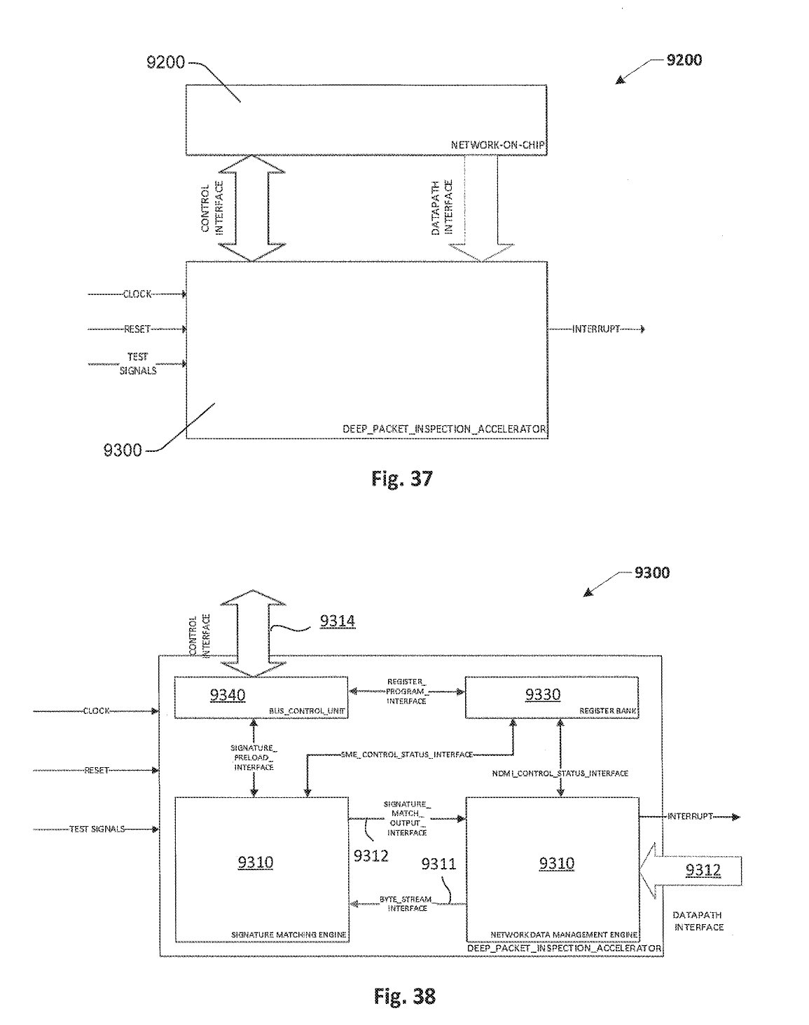

As described and incorporated from the '104 application, FIG. 37 describes an embodiment of “Deep Packet Inspection Accelerator” (DPIA) 9300 system architecture which may perform signature matching at line rates of 9.5 Gbps or higher and is scalable by multiplying the architecture, to handle throughputs of 40 Gbps and higher. In certain embodiments, the DPIA 9300 consists of two major interfaces for the accelerator, the control interface and the datapath interface. The control and the data interfaces enable easy integration with a hardware accelerator, particularly one designed as part of a network on chip (NoC).

In certain embodiments, the control interface performs two functions, first, to download the compressed signatures from a local/on-chip SRAM memory in, or associated with, a signature matching engine and secondly, to configure and access control memory registers in the DPIA 9300. The datapath interface allows the host processor or other accelerators/DMA engines in the SoC, to send the packet streams which have to be inspected by the DPIA 9300. The control and the datapath interfaces can be any standard interface such as OCP, AXI which can be used by the DPIA to connect to the NoC interconnect.

Apart from the control and datapath interfaces, the DPIA under test conditions, obtains the relevant clock, reset and test signals outside the control and datapath interfaces. Once a signature match is identified on the packet streams, an interrupt is raised to inform a software-based processor system to assume post-processing functionality including what to do with packet(s) after signature matching. Since a signature match is a rare occurrence in regular network traffic (i.e., an infrequent network event), the post-processing associated with any match may be handled with a general software-based processor solution to provide flexibility changing post-processing capabilities with signature matching rules in DPI applications.

DPIA Internal Architecture

FIG. 38 details a functional block level architecture of a DPIA circuitry 9300, according to one embodiment. DPIA 9300 circuitry may generally include a bus control unit (BCU) circuit 9320, a register bank (RB) circuit 9330, a signature matching engine (SME) 9310 circuit, and a network data management engine (NDME) circuit 9320.

The signature matching engine (SME) 9310 is an important circuit of the DPIA 9300, and adapted to store the signatures of content awareness applications in a compressed format, preferably in on-chip SRAM memory. The SME compares the incoming byte sequences of packet in incoming traffic streams using compressed signatures, e.g., compressed automata, to identify if there is a signature match in any of the network packets. In certain embodiments, a compiler may be used to convert the signatures into its compressed format based on one or more compression techniques.

In one embodiment, the network data management engine (NDME) 9320 is configured to receive network packets through the datapath interface and convert their respective payloads into a byte stream for signature matching. The NDME 9320 may also be configured to inform higher layer software/applications of signature matches by raising an interrupt determined by the SME 9310. Along with the interrupt, the NDME 9320 may be configured to provide state identification information associated with any signature matched packet. This information may be used by a separate processor system and associated application software to define actions to take for signature matched packets and their associated data stream. As used herein, content-awareness purpose functionality that is related to, or defines actions for, handling of matched packets/matched traffic streams, is referred to as “post-processing” functionality or “content-identified” handling/processing/functionality.

In some embodiments, the register bank (RB) 9330 stores the relevant configuration and status information of the DPIA 9320 on a local “on-chip” memory. The RB 9330 may be adapted to store two types of information, a first memory portion is, for example, one or more configuration registers which store information used to configure the internal functions of the DPIA 9300 such as those needed by the SME 9310 and NDMA 9320. A second memory portion in the RB 9330 stores status related information, for example in one or more status registers, to provide higher layers, e.g., application layer software, information pertaining to the status of the signature matching operations of the DPIA 9300.

The Bus Control Unit (BCU) module/circuit 9340 may function as an address decoder to decode incoming transactions (e.g., a read/write instruction) and forward the transactions to the RB 9330 and/or the SME 9310. The BCU 9340 may be configured to identify whether a transaction is targeted to the SME 9310 or the RB 9330, for example, based on whether an address of the transaction falls within a certain address range.

There may be a variety of internal interfaces of the DPIA 9300, examples of which are shown in the functional block diagrams of FIGS. 37, 38 and 39. In certain embodiments, these internal interfaces may include a signature preload interface and a register program interface. By way example, an incoming transaction in the BCU 9340 may be converted into a transaction in either of the signature preload interface or the register program interface. The signature preload and register program interfaces are used to provide address, control signals that indicate the type of transaction (read/write) and other associated data signals similar to an SRAM interface, in the DPIA 9300 of some embodiments. Depending on the DFA transition compression technique(s) used, there will be a variety of various memories which are part of the SME's 9310 functionality. All of these memories may be preloaded with information for signature matching by one or more SMEs 9310 using the signature preload interface circuitry. The control and status information of packet/byte processing by the SME 9310 and NDME circuits 9320 may be designated and stored in the RB 9330 as individual bits or group of bits. In certain example embodiments, the groups of signals in both of these cases, are referred to as “SME control status interface”/“NDME control status interface,” or just “control interface.”

According to some example embodiments, there may be two general I/O interfaces that communicatively couple to DPIA 9300 to a network processing circuit, a datapath interface 9322 and a control interface 9324. The control interface 9324 facilitates control signaling between the DPIA 9300 and a network adapter (9200; FIG. 37) while the datapath interface 9322 provides the DPIA 9300 access to network traffic packets being received.

Further, there are two basic interfaces that manage communications between an SME 9310 and the NDME 9320, a byte stream interface 9311 and a signature match output interface 9312. In some preferred embodiments, network packets come in through the datapath interface 9322, and if desired, are split into contexts (network packets classified into specific streams) before being sent through the byte stream interface to the SME 9310 as a stream of bytes. The byte stream may be inspected by the SME 9310 using loaded signature matching information, and information pertaining to a signature match may be sent through the signature match output interface 9312. The continuity with respect to the sequencing of the packet streams may also be maintained by the NDME 9320. This architecture design may assist in reducing irregularity in packet sequencing, which in turn leads to improper wrong signature matching results.

Scalability of the DPIA

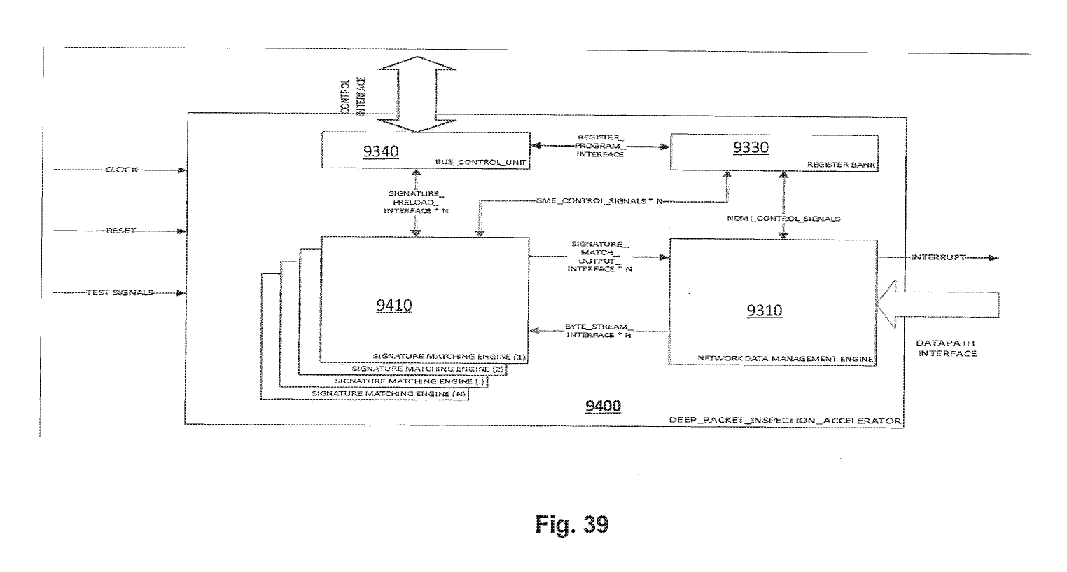

Each SME 9310 in the DPIA 9300 can perform signature matching at a fixed predefined throughput and can support a fixed signature count. In order to scale the DPIA 9300 to support increasing signature counts or increasing throughput, the SME 9310 can to be scaled accordingly. For example, assuming that each of the SME 9310 instance can perform signature matching at 10-Gbps, to support an overall throughput of 40-Gbps against a fixed signature count, four cores or “instances” of the SME 9310 is shown in the DPIA 9300 scalable embodiments of FIG. 39. Specifically, in order to support four times the number of signatures at 10-Gbps, four instances of the SME 9310 are used with same traffic sent to all four SME's 9310. FIG. 39 shows one example embodiment for a scalable DPIA 9400 architecture with N instances of SMEs 9410 demonstrating the scalability of the DPIA architecture of various embodiments. In order to scale the SME 9410 instances in the DPIA 9400, the associated interfaces should also be scaled similarly to that shown in FIG. 39.

Internal Block Level Architecture of SME

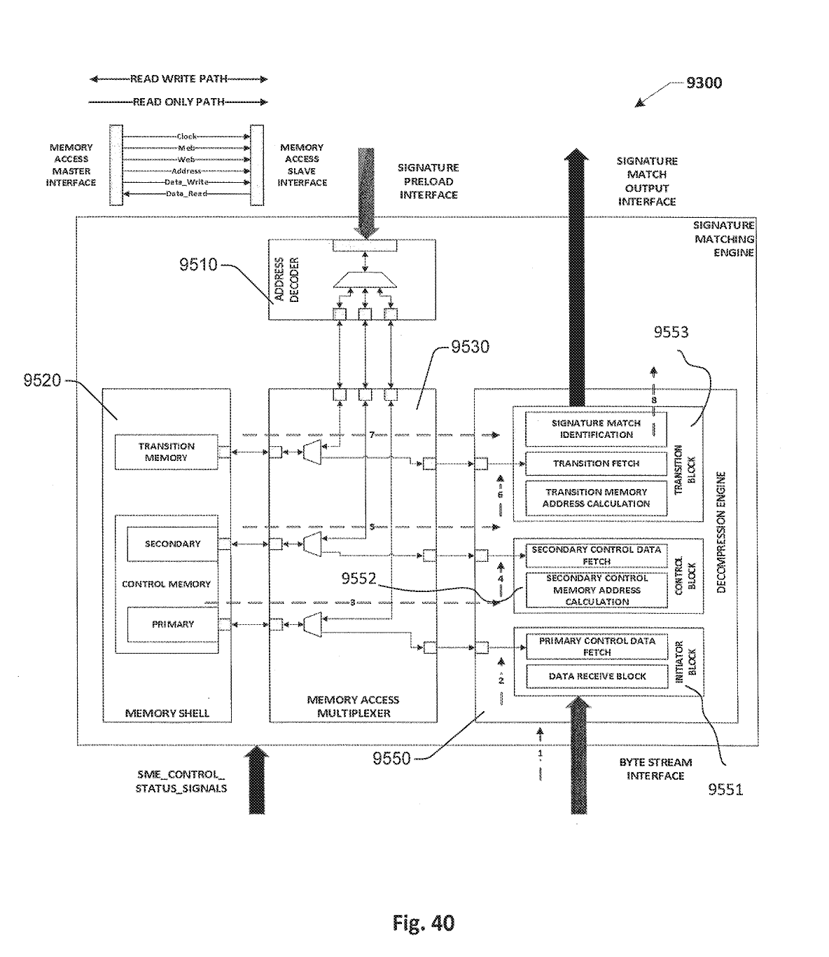

FIG. 40 shows one example functional block architecture of an SME 9300 of various embodiments, including four primary functional blocks including: an Address Decoder (AD) 9510, a Memory Shell (MS) 9520, a Decompression Engine (DE) 9550 and a Memory Access Multiplexer (MMA) 9530, which interact and function as described below.

In some example embodiments, a Memory Shell (MS) 9559 stores the signatures in its compressed format, preferably in on-chip SRAM memories. The individual memories inside the memory shell 9520 can broadly be classified into transition memory and control memory. The transition memories are configured to store actual compressed transitions representing signatures, e.g., compressed DFAs. The control memories may be configured to store certain control information used to locate the compressed transition corresponding to the payload byte in the transition memory. The control memory may be further partitioned into primary and secondary control memories.

In certain examples, a primary control memory is a small memory adapted to store information such as base addresses used for further processing. The secondary control memory stores more detailed control information such as bitmaps, bitmasks and the like used to identify if a transition is compressed and/or how to access the compressed signatures. Memory blocks belonging to the memory shell 9520 can either be made up of single or multiple individual physical memory blocks.

In some embodiments of an SME, an Address Decoder (AD) 9510 receives signatures to match through signature preload interface from the bus control unit. The basic function of the AD is to convert the incoming memory transactions to its corresponding memories in the MS 9520. The address decoder 9510 may identify which interface a transaction should be directed to based on the address, of a range of addresses of an incoming transaction as mentioned previously.

According to certain embodiments, the Decompression Engine (DE) 9550 is adapted to receive the network packet payload bytes, i.e., byte stream and scan (or compare) them against the compressed signatures. During scanning of the bytes against the compressed signatures, the DE 9550 may generate a signature detect signal, including a stateID used to further identify the exact details of a signature, when a match occurs. The byte stream interface may provide the network data bytes along with the state information.

In some example embodiments, there are three processing blocks included in the DE 9550: an initiator block 9551, a DE control processing block 9552 and DE transition processing block 9553. These functions may be further split into two further sub-blocks, a first sub-block configured to receive the data from the previous blocks and perform calculations on the received data to generate address locations in the memory shell for the data to be fetched from the current block. For example, if the current block is the control processing block 9552, it would receive the data fetched from the primary control memory and calculate the location for the data to be fetched from the secondary control memory. A second sub-block functions to populate the interface signals to generate a transaction directed toward one or more corresponding memories.

In certain embodiments, the SME 300 functions as a Memory Access Multiplexer (MAM) 9530 configured to enable access to memories in the memory shell (MS) 9520 for both the decompression engine (DE) 9550 and the address decoder (AD) 9510. The AD 9510 may access the memories as part of a signature download phase while the DE 9550 accesses them during a signature match phase. The MAM 9530 multiplexes the transactions accordingly during these operations. Once the download phase is over, the control over accessing the memories is given to the DE 9550. In preferred embodiments, when the DE 9550 is in operation, the AD 9510 is limited from accessing the MS 9520 to ensure the integrity of the signature matching operation is always maintained. Moreover, when the signature matching is being performed by the DE 9550, preferably, there should be no changes to the compressed signature representation, as this may affect the integrity of the signature matching. This also allows that the contents of the memories not to be modified during the signature matching phase/process. Lastly, it is preferable that the DE 9550 may only read the contents from the memory and cannot modify its contents. The AD 9510 may be controlled by software/other accelerators and exclusively be allowed to modify the content of the memories in MS.

DPIA—Compression Mechanism Independent

In various embodiments, the compressed signature set generated after transition compression is segregated into transition and control information and split in logical blocks to facilitate storage and processing for control and transition blocks.

From a functional point of view, the block level architecture of the DE of the various embodiments, is independent of the underlying transition compression technique and processes. The DE features to receive the payload bytes, compare them against the compressed automata and generate a match signal, may be independent of the compression mechanism to generate the compressed automata.

As the content of memories change, any calculations involved in the address computation will also change. Other than this, the architecture of the engine external to the SME can be unchanged according this knowledge. This segregated framework provides the flexibility to modify the compression methodology to improve the efficiency of the transition compression and improve the memory usage.

FIG. 40 also shows a process sequence of signature matching according to one embodiment (by arrow dashed lines) and includes a sequence of steps (1-8) performed in the SME corresponding to one payload byte and one DFA state. Initially, a byte being inspected and a state ID corresponding to the state, are received (1) as inputs through the byte stream interface as the initiator block receives the byte and the state ID. Next, the address location for the data may be fetched (2) in the primary control memory for the current character, state ID combination.

The initiator block may further populate the memory access to generate a memory read request to find a base address in memory. Data is fetched (3) from the control memory corresponding to the calculated address location may then be directed (4) towards the control block. The control block uses fetched information to calculate the address location for the secondary control memory from which the data will be fetched (4) for the current character/state ID combination. The secondary control memory access interface is populated to fetch this data from the control memory.

Data fetched (5) from the secondary control memory relating to the calculated address location is directed towards the transition block. In certain embodiments, the transition block first calculates the address location of the compressed transition to be fetched from the transition memories. The transition memory interface is populated to generate a memory access in the interface. The compressed transition is received (7) by the transition block and used for signature matching comparison.

In one example, the signature match identification sub block investigates the compressed transition to identify if there is a signature match in it. The most significant bit is ‘1’ in the compressed transition that is fetched from the memory if there is a signature match associated with the character, stateID combination. If the most significant bit is ‘0’, then there is no signature match associated with the character, stateID combination. The stateID is sent to the next layer for further post-processing.

Hardware-Software Interaction in DPIA

Once the signature set is converted into the automata, only a very small portion of the states in the automata belong to the subset of accepted states. As mentioned earlier, accepted states are those, which when reached, that represent a signature match. Once a signature match is identified, the accepting state is the only information that is available from the SME, is used to determine the corresponding post-processing step. In order to support varied post-processing steps and support scalable signature counts, it is preferable to de-couple this post-processing from the DPIA hardware acceleration. This also gives the software the additional flexibility in defining and performing the post-processing tasks after a signature match.

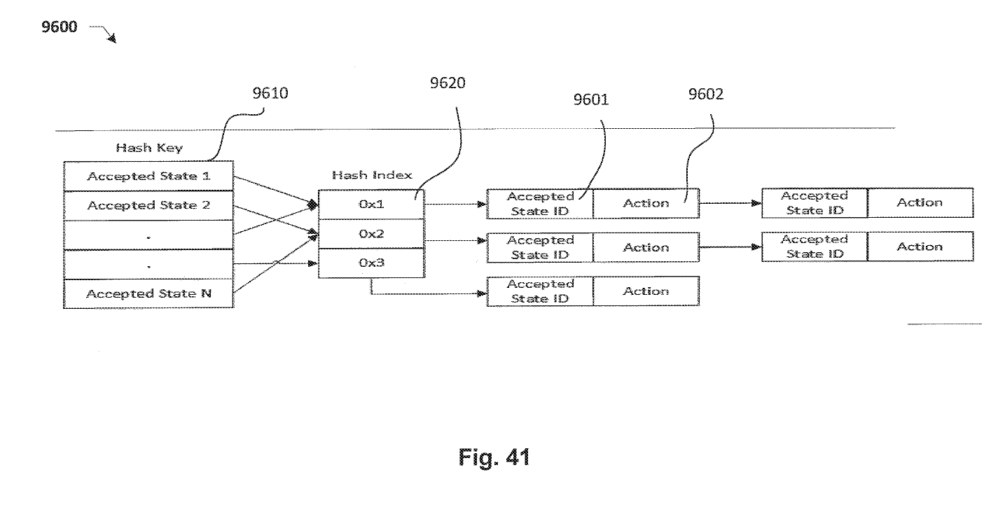

FIG. 41 illustrates post-processing actions are stored in memory (not on-chip SRAM memories) corresponding to the signature matches. Actions which have to be performed associated with a signature match can be uniquely identified through the accepted state ID 9601. Since the accepted state count varies with the number of signatures, a hash table 9610 is used as the data structure to store the corresponding actions 9602. The accepted state identification 9601 (can be an integer), is used as the hash key to identify the memory location (index) of the corresponding post-processing action. A linked list implementation can be used in the hash table 9610 at each index 9610 to solve any problems arising from hash collisions as shown in FIG. 96. After traversing through the hash indices, the post-processing action can be performed after a simple comparison operation to check the accepted state ID's.

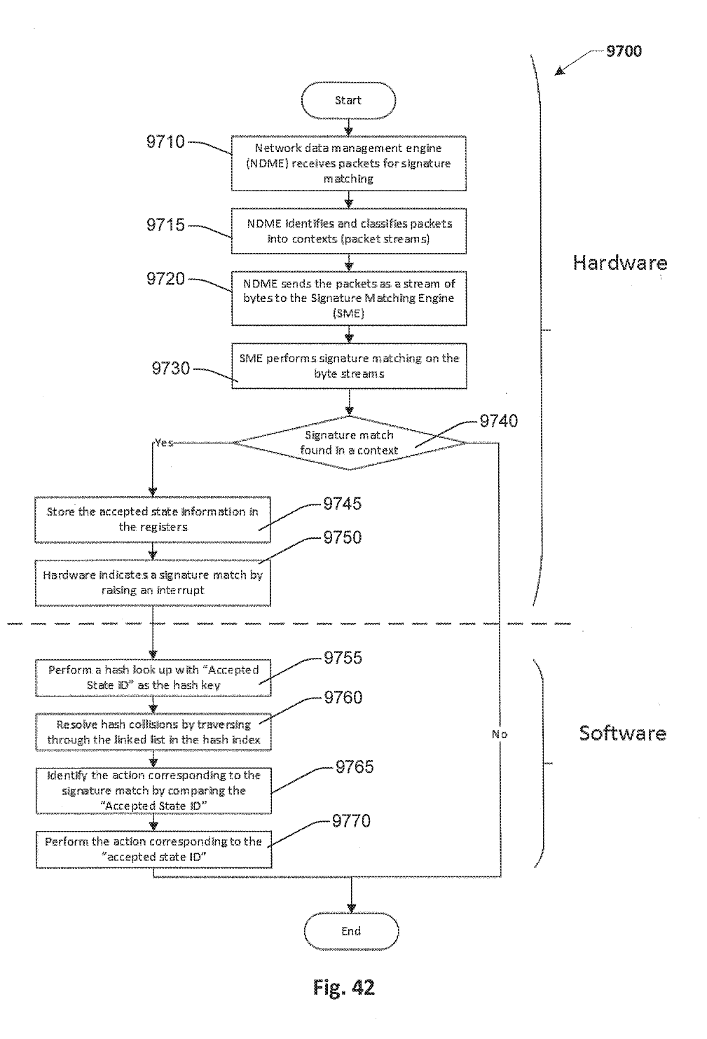

FIG. 42 illustrates a flowchart 9700 of events occurring as part of the hardware software co-architecture in DPIA. The first step 9710 is the arrival of packets into the NDME, which are received and stored the packets in a local buffer over the datapath interface. In some embodiments, the packet may already be classified 9715 based on the header inspection and NDME converting the packet to a certain local context.

Next, the NDME sends the payload bytes 9720 of the context as a stream of bytes to the SME to perform signature matching 9730, i.e., the SME can either find a signature match or not find a signature match in the stream of bytes. If 9740 a signature match is found in the stream of bytes, the NDME stores 9745 the accepted state information in the hardware status register, which, in certain example embodiments, is included in the register bank (RB), and raises an interrupt for a separate processor 9750 running software to take over further processing. The software reads the accepted stateID from the RB and performs a hash lookup 9755 with the same. Post-processing actions, i.e., what happens after signature is matched or not, may be read 9765 and, if desired, executed 9770 based on the address location determined from the hash lookup 9755. Once the post-processing action is identified 9765, the corresponding action is performed 9770 on the network stream as designated by code in the programed software portion executed by a processor apart from the DPIA.

In some embodiments, after generating an interrupt 9750, the hardware can further continue to perform signature matching on the next incoming packets. Alternatively, the software may assume any post-processing function as the hardware simultaneously inspects the packet payloads. Depending on the number of SME slices the hardware supports, either single or multiple interrupt lines can be used to support the post-processing function.

### Example Embodiments

In a First Example embodiment, a device is disclosed for signature matching network traffic using deterministic finite automata (DFA), the device comprising: a register bank (RB) circuit configured to store configuration and status information relating to signature matching; a bus control unit (BCU) circuit to decode addresses of the configuration and status information; at least one signature matching engine (SME) circuit adapted to store signatures for content awareness matching in a compressed format, compare incoming byte sequences of packet in incoming traffic streams using compressed signatures expressed in at least one compressed DFA, to identify if there is a signature match in any of the network packets; and a network data management engine (NDME) configured to provide the incoming byte sequences from the incoming traffic streams to the at least one SME.

A Second Example embodiment further defines the first wherein the SME comprises: an address decoder configured to decode an incoming read or write access transactions and store signatures as part of a signature download phase; a memory shell (MS) comprising a primary memory and a secondary memory, the MS adapted to provide memory in partitions related to the transition circuitry and the control circuitry; a decompression engine (DE) to access memories during a signature match phase in which bytes of the incoming byte stream to compressed signatures using the compressed DFA; and a memory access multiplier (MAM) to multiplex transactions for multiple instances of the decompression engine.

In a Third Example embodiment, the device of claim 1 or 2 is furthered wherein the device comprises a hardware accelerator operative regardless of any type of compression technique used to compress the DFA.

A Fourth Example embodiment further defines the prior examples by including a signature preload interface to provide compressed signatures to the at least one SME based on addresses provided by the BCU; and a register program interface to manage communication between the at least one SME and the NDME.

A Fifth Example embodiment furthers any of the prior examples by including four SMEs coupled to the NDME in parallel and configured to process the incoming byte stream in parallel to increase signature matching throughput of the by four times.

In a Sixth Example embodiment, a method is disclosed for comparing signatures in a DPI signature matching hardware accelerator, the method comprising: loading compressed signatures of deterministic finite automata (DFA) compressed using any compression technique independent of the hardware accelerator, into memory of the hardware accelerator as part of a signature download phase; and determining if the incoming matches a compressed signature in a second signature matching mode by: comparing bytes of incoming byte sequences from packet payloads of incoming traffic streams using the loaded compressed DFA, to identify if there is a signature match in any of the network packets; and generating a signature match output signal when the signature match is detected, the signature match output signal provided to a separate processing system running software and handling post-signature match processing actions.

In a Seventh Example embodiment, the Sixth Example is furthered by the determining comparing and generating steps being performed in a hardware accelerator including multiple scalable signature matching engines.

In an Eighth Example embodiment, the methods of the Sixth and Seventh Examples are performed in a hardware acceleration circuit.

In an Ninth Example embodiment, a system is disclosed which includes a processing circuit having at least one processor executing machine readable instructions to compress signatures of content aware applications using one or more deterministic finite automata (DFA) compressed using any compression technique; and a hardware accelerator circuit including a register bank (RB) circuit configured to store configuration and status information relating to signature matching; a bus control unit (BCU) circuit to decode addresses of the configuration and status information, at least one signature matching engine (SME) circuit adapted to store signatures for content awareness matching in a compressed format, compare incoming byte sequences of packet in incoming traffic streams using compressed signatures expressed in at least one compressed DFA, to identify if there is a signature match in any of the network packets; and a network data management engine (NDME) configured to provide the incoming byte sequences from the incoming traffic streams to the at least one SME.

As with other example embodiments described herein, the various embodiments relating to other innovations described above are specifically disclosed to be used in combinations with example embodiments disclosed in other sections. For example, the forgoing compression embodiments are disclosed for use in combination with other example embodiments. Embodiments of context based pipelining, a hardware accelerator or decompression engine disclosed here, using alphabetic and bitmap-based compression processes as shown and described herein, packed storage architecture shown and described herein, are all intended to be combined where possible.

While embodiments of an example apparatus has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention.

In particular regard to the various functions performed by the above described components (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure. In addition, while a particular feature may have been disclosed with respect to only one of several implementations, such feature may be combined with one or more other features of the other implementations as may be desired and advantageous for any given or particular application.

Examples can include subject matter such as a method, means for performing acts or blocks of the method, at least one machine-readable medium including instructions that, when performed by a machine cause the machine to perform acts of the method or of an apparatus or system for concurrent communication using multiple communication technologies according to embodiments and examples described herein.

1. A device for signature matching using deep packet inspection (DPI) to detect content aware application in incoming packets of a communications network using deterministic finite automata (DFA) representing signatures to be matched, the device comprising:
a leader-state transition table (LTT) memory;
a member-state transition table (MTT) memory;
an alphabet transition table (ATT) memory; and
DPI processing circuitry coupled to said memories, the DPI processing circuit configured to perform an alphabet compression process on the DFA to simplify indistinguishable characters and corresponding state transitions into an encoded DFA representation to store in the ATT memory, and to perform a bitmap compression process on the encoded DFA representation to reduce redundant state transitions and store in the LTT and MTT memories.

2. The device of claim 1 further comprising:
data fetch circuitry coupled to the DPI processing circuit to apply packet data to the alphabet and bitmap compressed DFA and identify matching signatures.

3. The device of claim 1 wherein the ATT memory is configured to store 256 encoded DFA entries, each entry being 8-bits wide.

4. The device of claim 1 wherein the DPI processing circuitry comprises:
a decompression engine including a set of primary inputs and a set of primary outputs, wherein the set of primary inputs include a character input to provide a byte stream from payloads of the incoming packets to be signature matched, and a state input to provide information based on the alphabet and bitmap compressed DFA for which an instance of signature matching on each byte in the byte stream is either started or continued from, and wherein said set of primary outputs include a signature match detect signal when a signature match is detected and information related to the signature match.

5. The device of claim 1 wherein the bitmap compression process comprises: (i) an intra-state compression of the alphabet compressed encoded DFA representation using bitmaps, (ii) transition state grouping to group similar bitmaps into leader and corresponding member groups; and (iii) inter-state compression applied to the leader and corresponding member groups using bitmasks.

6. The device of claim 1 wherein the DPI circuitry operates in two modes, a compression mode to apply alphabet compression and bitmap based compression to the DFA and a fetch mode to signature match bytes of the incoming packets using the alphabet and bitmap based compressed DFA.

7. The device of claim 1 wherein the DPI circuitry includes address lookup circuit to identify memory addresses relating to the LTT, MTT and ATT memories, a leader transition bitmask fetch circuit and a member transition fetch circuit.

8. A hardware accelerator circuit for deep packet inspection signature matching in a communications node using deterministic finite automata (DFA) representing character signatures for matching, the hardware accelerator circuit comprising:
a processing circuit adapted to accelerate DPI signature matching using compressed DFA by first compressing DFA using an alphabet compression process and a bitmap compression process and then perform signature matching on bytes of incoming packets using the compressed DFA; and
a memory coupled to the processing circuit adapted to store representations of the alphabet and bitmap compressed DFA.

9. The hardware accelerator circuit of claim 8 wherein the memory comprises a static random access memory (SRAM) partitioned into an alphabet transition table (ATT) to store encoded information of alphabet compressed DFA and a leader-state transition table (LTT) and member-state transition table (MTT).

10. The hardware accelerator circuit of claim 8 wherein the processing circuit includes:
a decompression engine including a set of primary inputs and a set of primary outputs, wherein the set of primary inputs include a character input to provide a byte stream from payloads of the incoming packets to be signature matched, and a state input to provide information based on the alphabet and bitmap compressed DFA for which an instance of signature matching on each byte in the byte stream is either started or continued from, and wherein said set of primary outputs include a signature match detect signal when a signature match is detected and information related to the signature match.

11. The hardware accelerator circuit of claim 8 further comprising:
data fetch circuitry adapted to apply packet data to the alphabet and bitmap based compressed DFA and identify matching signatures.

12. The hardware accelerator circuit of claim 9 wherein the ATT memory is configured to store 256 encoded DFA entries, each entry being 8-bits wide.

13. The hardware accelerator circuit of claim 8 wherein the bitmap compression process comprises: (i) an intra-state compression of the alphabet compressed encoded DFA representation using bitmaps, (ii) transition state grouping to group similar bitmaps into leader and corresponding member groups; and (iii) inter-state compression applied to the leader and corresponding member groups using bitmasks

14. The hardware accelerator circuit of claim 8 wherein the processing circuit operates in two modes, a compression mode to apply alphabet compression and bitmap based compression to the DFA and a fetch mode to signature match bytes of the incoming packets using the alphabet and bitmap based compressed DFA.

15. The hardware accelerator circuit of claim 8 wherein the processing circuit includes address lookup circuit to identify memory addresses relating to the LTT, MTT and ATT memories, a leader transition bitmask fetch circuit and a member transition fetch circuit.

16. The hardware accelerator circuit of claim 8 wherein the processing circuit and the memory are located on a same chip.

17. A process for signature matching in deep packet inspection (DPI) using a signature set converted into a discrete finite automaton comprising a state machine table representation of signature characters of the signature set, as a plurality of state nodes and state transitions, the method comprising:
simplifying the automaton to compress indistinguishable or unused characters of the signature set and their corresponding state transitions using an alphabet compression process to provide an encoded automaton;
applying a bitmap-based compression process on the encoded automaton; and
fetching packet data for comparison by the bitmap-based compressed automaton to identify if any signature matches are present in the fetched packet data.

18. The process of claim 17 further comprising:
storing a representation of the encoded automaton in an alphabet transition table (ATT); and
storing bitmap-based compression information of the encoded automaton in a leader-state transition table (LTT) and member-state transition table (MTT).

19. The process of claim 17 wherein the bitmap-based compression process comprises:
performing intra-state compression of redundant adjacent character transitions of the encoded automaton, segmenting the intra-state compressed automaton into groups having matching bitmaps and designating a leader state and one or more member states for each group; and performing inter-state compression of redundant transitions of member states for each group.

20. The process of claim 18 wherein the ATT memory is configured to store 256 encoded DFA entries, each entry being 8-bits wide.
